(19) United States
(12) Patent Application Publication
(10) Pub. No.: US 2024/0371693 A1
(43) Pub. Date: Nov. 7, 2024

(54) TECHNIQUES FOR DICING BONDED WAFERS USING LASER TECHNOLOGIES

(71) Applicant: CORNING INCORPORATED, Corning, NY (US)

(72) Inventors: Andreas Simon Gaab, Grobenzell (DE); Nicolai Martin Haenel, Munchen (DE); Roni Daniel Levi, Corning, NY (US); Bernhard Anton Moegele, Landsberg am Lech (DE); Ralf Joachim Terbrueggen, Neuried (DE)

(21) Appl. No.: 18/652,102

(22) Filed: May 1, 2024

Related U.S. Application Data
(60) Provisional application No. 63/463,962, filed on May 4, 2023.

(51) Int. Cl. H01L 21/768; H01L 21/20; H01L 21/683

(52) U.S. Cl. CPC H01L 21/76894; H01L 21/2007; H01L 21/6835

(57) ABSTRACT

Methods, systems, and devices implementing techniques for dicing bonded wafers using laser technologies are described. A bonded wafer includes an optically transmissive substrate bonded with a semiconductor substrate. The optically transmissive substrate is irradiated using a first laser technology associated with perforating the optically transmissive substrate to form damage tracks. The semiconductor substrate is irradiated using a second laser technology associated with forming damage regions within the semiconductor substrate. The damage regions of the semiconductor substrate are aligned with the damage tracks of the optically transmissive substrate during irradiation of the semiconductor substrate or the optically transmissive substrate, forming an aligned region through the bonded wafer with a relatively high likelihood for fracture. After irradiating the optically transmissive substrate and the semiconductor substrate, one or more forces may be applied to the bonded wafer to separate the bonded wafer into respective dies along the aligned region.

This application claims the benefit of priority under 35 U.S.C § 120 of U.S. Provisional Application Ser. No. 63/463,962 filed on May 4, 2023, the content of which is relied upon and incorporated herein by reference in its entirety.

### FIELD OF TECHNOLOGY

The present disclosure relates generally to wafer dicing, and more specifically to techniques for dicing bonded wafers using laser technologies.

### BACKGROUND

Wafers including semiconductor materials are key components for fabricating various electronics, such as integrated circuits and photovoltaic cells, among other examples, and such electronics may accordingly have a wide range of industrial, academic, and commercial applications (e.g., computers, vehicles, wearable devices such as smartwatches, mobile electronic devices such as smartphones and tablets, and the like). A wafer may be separated (e.g., diced, singulated) into multiple dies that each include one or more electronic or micro-electronic devices that are assembled on and/or in the wafer. In some cases, a wafer may include multiple materials, such as a glass material bonded with a semiconductor material (e.g., crystalline silicon), and may be referred to as a bonded wafer or a stacked wafer. The bonded wafers, however, may provide various challenges to the dicing process due to respective properties of the bonded materials. For instance, some dicing techniques may be fitting for dicing one material, yet may be disadvantageous for dicing the other material(s) of the bonded wafer, resulting in various manufacturing inefficiencies. Moreover, some dicing techniques may unnecessarily remove excess material from the wafer, and/or may potentially cause damage to some portion of the bonded wafer (e.g., including any electronic devices included on/in the wafer), among other disadvantages.

### SUMMARY

The described techniques relate to improved methods, systems, devices, and apparatuses that support techniques for dicing bonded wafers using laser technologies. Generally, the described techniques are directed to forming dies from a bonded wafer that includes multiple materials using a combination of laser technologies on various substrates of the bonded wafer. For example, a bonded wafer may include an optically transmissive substrate and a semiconductor substrate. A first laser technology may be applied for the optically transmissive substrate and a second laser technology may be applied for the semiconductor substrate. The first and second laser technologies may form aligned damage tracks and damage regions, respectively, that are prone to fracture when mechanical forces are applied to the bonded wafer. Specifically, after applying the first and second laser technologies, one or more mechanical forces may be applied to the bonded wafer to separate the bonded wafer into a desired quantity of dies. The application of such laser technologies for dicing a bonded wafer may improve dicing processes while enabling minimal material loss from dicing (e.g., relatively low- or zero-kerf process), thereby enabling enhanced manufacturing schemes and more efficient use of the wafer material(s), among other advantages.

A method is described. The method may include irradiating a first substrate of a bonded wafer using a first laser beam, the bonded wafer comprising the first substrate coupled with a second substrate. In some examples, the first substrate is irradiated from a first direction that is orthogonal to a surface of the first substrate, and the first substrate comprises a first material and the second substrate comprises a second material different than the first material. In some examples, the method may include irradiating the second substrate of the bonded wafer using a second laser beam different than the first laser beam, wherein the second substrate is irradiated from a second direction opposite the first direction. In some examples, the method may include applying one or more forces to the bonded wafer to separate the bonded wafer into a plurality of dies that are formed after irradiating the first substrate and the second substrate.

Another method is described. The method may include irradiating a first substrate of a bonded wafer using a first laser beam, the bonded wafer comprising the first substrate coupled with a second substrate. In some examples, the first substrate is irradiated by the first laser beam through the second substrate and from a first direction that is orthogonal to a surface of the second substrate, and the first substrate comprises a first material and the second substrate comprises a second material different than the first material. In some examples, the method may include irradiating the second substrate of the bonded wafer using a second laser beam different than the first laser beam, wherein the second substrate is irradiated from the first direction. In some examples, the method may include applying one or more forces to the bonded wafer to separate the bonded wafer into a plurality of dies that are formed after irradiating the first substrate and the second substrate.

A bonded wafer is described. The bonded wafer may include an optically transmissive substrate layer coupled with a semiconductor substrate layer, wherein the optically transmissive substrate layer comprises a plurality of damage tracks from a first laser source that extend at least partially from a surface of the optically transmissive substrate layer through a thickness of the optically transmissive substrate layer. In some examples, the semiconductor substrate layer comprises a plurality of regions that are damaged by a second laser source focused within a volume of the semiconductor substrate layer, wherein the plurality of damage tracks are aligned with the plurality of regions that are damaged and form one or more contour lines on the bonded wafer.

### BRIEF DESCRIPTION OF THE DRAWINGS

FIG. 1 shows an example of a system that supports techniques for dicing bonded wafers using laser technologies in accordance with examples as disclosed herein.

FIGS. 2A and 2B show examples of a bonded wafer that support techniques for dicing bonded wafers using laser technologies in accordance with examples as disclosed herein.

FIGS. 3A, 3B, and 3C show examples of processing steps that support techniques for dicing bonded wafers using laser technologies in accordance with examples as disclosed herein.

FIGS. 4A, 4B, and 4C show examples of processing steps that support techniques for dicing bonded wafers using laser technologies in accordance with examples as disclosed herein.

FIGS. 5A, 5B, and 5C show examples of processing steps that support techniques for dicing bonded wafers using laser technologies in accordance with examples as disclosed herein.

FIGS. 6 through 9 show flowcharts illustrating methods that support techniques for dicing bonded wafers using laser technologies in accordance with examples as disclosed herein.

### DETAILED DESCRIPTION

Bonded wafers (e.g., wafers including two or more substrates) including an optically transmissive substrate and a semiconductor (e.g., or chalcogenide) substrate may have a range of uses in various products and industries. For example, a bonded wafer may be used in applications including an electrical circuit on one side of a product (e.g., associated with the semiconductor substrate) and an optically (e.g., electromagnetically, radiationally) transparent substrate on another side of the product (e.g., associated with the optically transmissive substrate). In some cases, the bonded wafers may be processed to form dies (e.g., sections of a bonded wafer the comprise functional subunits such as, for example, circuits, optical properties, and/or microchannels) which may be desirable for implementation in the applications described. In some such cases, forming the dies (which may also be referred to as dice) from a bonded wafer may involve one or more dicing processes (e.g., cutting processes, segmenting processes), which may be disadvantageous to implement for at least one of the substrates in the bonded wafer. For example, implementing a process for dicing the optically transmissive substrate may adversely affect the semiconductor substrate, or vice versa. In some such examples, one of the substrates in the bonded wafer may be damaged from implementing a process that is unsuitable for that one substrate. Moreover, some techniques may remove extra material(s), which may affect the design and placement of components on or in one or both of the substrates (e.g., when excess material is removed via the dicing process(es), a functional area used for associated electronics such as integrated circuits on a substrate may be reduced, resulting in inefficient use of the wafer materials).

As an example, a mechanical dicing process may be used to form the dies from the bonded wafer. The mechanical dicing process may include applying a high-speed blade or rotating wheel to a surface of the bonded wafer. In some examples, the mechanical dicing process may be associated with additional damage to one or both of the substrates and/or additional material removal (e.g., kerf-loss). In some cases, mechanical dicing may be damaging or relatively less effective on some materials, for example, when performed on the optically transmissive substrate, but relatively more effective when performed on the semiconductor substrate (e.g., based on one or more material properties that differ between the respective materials). Further, performing mechanical dicing on multiple substrates (e.g., sequentially) may involve dynamically modifying aspects of the mechanical dicing process, such as changing blades or wheels (e.g., to a thicker or thinner variation), altering speed, or adjusting angle or cutting depth, among other possibilities, to better suit the relevant substrate. However, modifying aspects of the mechanical dicing process may be associated with relatively high processing durations, which may be disadvantageous.

In other cases, a plasma dicing process, a jet dicing process (e.g., water jet dicing), or other mechanically-based or chemically-based dicing processes may be used to form the dies from the bonded wafer. But such dicing process may be associated with similar challenges as the mechanical dicing process, such as dicing one substrate only to adversely affect the other substrate. For example, jet dicing may be associated with generating unwanted debris and being relatively cost inefficient, among other disadvantages, which may impact the application to multiple materials of a bonded wafer. As such, dicing bonded wafers may be associated with various challenges, and some dicing techniques applied to bonded wafers may impact manufacturing time, cost, and efficiency when creating multiple dies from the bonded wafer.

In accordance with examples described herein, a bonded wafer including an optically transmissive substrate (e.g., a glass material) and a semiconductor (e.g., or chalcogenide) substrate (e.g., a monocrystalline silicon) may be diced using different laser technologies. For example, the optically transmissive substrate may be irradiated using a first laser technology and the semiconductor substrate may be irradiated using a second laser technology, where the first laser technology and the second laser technology are configured for damaging the respective materials of the optically transmissive substrate and the semiconductor substrate. For instance, the first laser technology is configured for modifying a material of the optically transmissive substrate (e.g., an amorphous material), whereas the second laser technology is configured for modifying a material of the semiconductor substrate (e.g., a crystalline material). In some examples, the first laser technology may implement techniques (e.g., nano-perforation techniques) to modify the material of the optically transmissive substrate, which may include directing a quantity of pulses, pulse bursts, or sub-pulses of a laser beam toward a surface of the optically transmissive substrate, thereby forming damage tracks associated with perforating the optically transmissive substrate. In some such examples, the damage tracks may form trenches (at least partially) through the optically transmissive substrate which may result in a relatively weak resistance to mechanical forces (e.g., bending forces, tensile forces, shear forces) when applied to the bonded wafer. In some examples, the second laser technology may implement techniques for focusing a pulsed laser beam at targeted regions within a volume of the semiconductor substrate. In some such examples, the targeted regions may correspond to one or more layers of the semiconductor substrate, and damage regions (e.g., including material that is damaged modified by the laser beam) caused by the focused laser beam may thereby increase a likelihood of fracture propagation through the semiconductor substrate, particularly when mechanical forces (e.g., bending forces, tensile forces, shear forces) are applied to the bonded wafer. In some aspects, the second laser technology may be referred to as stealth dicing or some similar terminology.

The damage tracks and damage regions resulting from the application of the first and second laser technologies to the bonded wafer, respectively, may be aligned relative to the bonded wafer (e.g., or to each other) such that the damage tracks and the damage regions may be aligned (e.g., using optical alignment) along a plane, which may form a fracture mode under mechanical force. In some aspects, the damage tracks and/or damage regions correspond to respective contour lines (e.g., modification lines, modification pathways) in the optically transmissive substrate and the semiconductor substrate, where a contour line is associated with a desired geometry (which may be linear or may not be linear) of the respective dies created from dicing the wafer. After the first and second laser technologies are applied to the respective substrates, one or more mechanical forces may be applied to the bonded wafer to separate the bonded wafer into the respective dies. For example, the damage tracks in the optically transmissive substrate (e.g., formed using nano-perforation) and the damage regions in the semiconductor substrate (e.g., using stealth dicing) may be aligned along a plane, thereby enabling the bonded wafer to be separated into the respective dies along the plane.

Dicing the bonded wafer using the combination of laser technologies as described herein, may be associated with advantageous results for the substrates of the bonded wafer. For example, using the first laser technology to form damage tracks through the optically transmissive substrate may produce a relatively fast, accurate cut through the optically transmissive substrate. However, unlike other dicing processes, the first laser technology may not be associated with causing damage or accidental material removal to the semiconductor substrate. Likewise, using the second laser technology to form damage regions in the semiconductor substrate may produce an accurate separation through the semiconductor substrate without causing damage or accidental material removal to the optically transmissive substrate. Therefore, implementing the combination of laser technologies as described herein may support accurate dicing for the bonded wafer without adversely affecting the substrates thereof.

Aspects of the disclosure are initially described in the context of a system implementing techniques for dicing bonded wafers using laser technologies. Further examples of process steps for dicing bonded wafers using laser technologies are also provided. Aspects of the disclosure are further illustrated by and described with reference to flowcharts that relate to techniques for dicing bonded wafers using laser technologies.

This description provides examples, and is not intended to limit the scope, applicability or configuration of the principles described herein. Rather, the ensuing description will provide those skilled in the art with an enabling description for implementing various aspects of the principles described herein. As can be understood by one skilled in the art, various changes may be made in the function and arrangement of elements without departing from the application.

It should be appreciated by a person skilled in the art that one or more aspects of the disclosure may be implemented in a system to additionally or alternatively solve other problems than those described herein. Further, aspects of the disclosure may provide technical improvements to other (e.g., “conventional”) systems or processes as described herein. However, the description and appended drawings include example technical improvements resulting from implementing aspects of the disclosure, and accordingly do not represent all of the technical improvements provided within the scope of the claims and the disclosure.

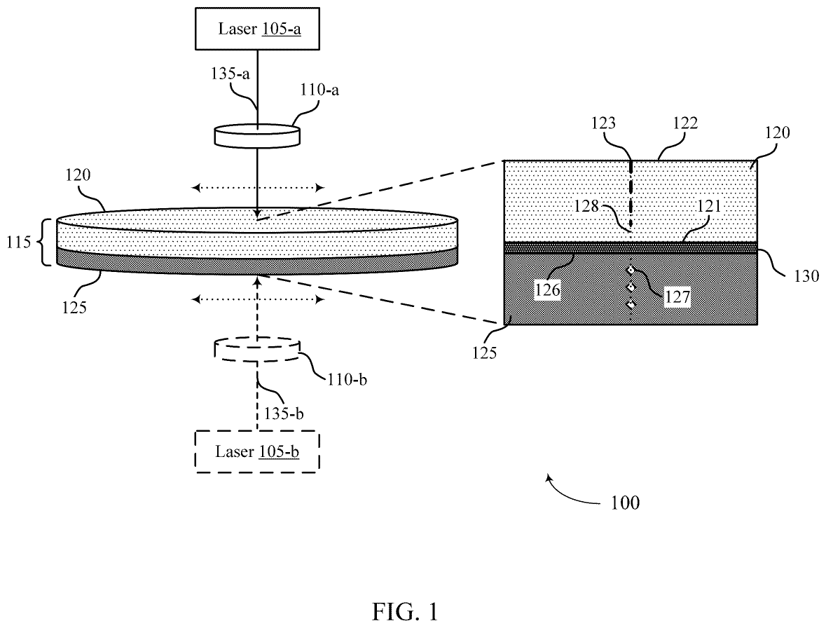

FIG. 1 shows an example of a system 100 that supports techniques for dicing bonded wafers using laser technologies in accordance with examples as disclosed herein. The system 100 may include various laser components and optical components operable to modify two or more substrates of a bonded wafer. For example, the system 100 may include one or more lasers (e.g., a first laser 105-a, a second laser 105-b) and one or more optical components (e.g., optical components 110-a, optical components 110-b) configured to dice a bonded wafer 115. In some examples, the system 100 may be an example of a device or system used for applying one or more laser technologies to form regions of the bonded wafer 115 with a high likelihood for fracture under force for segmenting the bonded wafer 115 into a quantity of dies. In some examples, the system 100 may implement the laser technologies such that each laser technology may be associated with irradiating one of the substrates of the bonded wafer 115 without adversely affecting (or with minimal impact on) the other substrate or components of the bonded wafer 115. That is, the lasers may be used for dicing of the bonded wafer 115 into multiple dies with improved efficiency.

The bonded wafer 115 may have some dimension, for example, based on an application for the dies of the bonded wafer 115 (e.g., after dicing) or other factors. For example, the bonded wafer 115 may be between about 25 millimeters (mm) and about 450 mm in diameter. In some examples, the bonded wafer 115 may be about 300 mm in diameter, or about 200 mm in diameter, or about 150 mm in diameters, among other examples. The bonded wafer 115 may include an optically transmissive substrate 120 bonded with a semiconductor substrate 125. The optically transmissive substrate 120 may be a glass material (e.g., hardened glass) or another material (e.g., an insulating material) including a crystalline atomic structure, or a combination thereof, among other examples. In some aspects, the optically transmissive substrate 120 may be an example of a glass material including one or more glass compositions. For example, the optically transmissive substrate 120 may include a soda-lime glass material, a borosilicate glass material, an aluminosilicate glass material, an alkali aluminosilicate glass material, an alkaline earth aluminosilicate glass material, an alkaline earth boro-aluminosilicate glass material, a fused silica glass material, a crystalline material (e.g., sapphire, silicon carbide, other materials, or any combination thereof), among other examples. The optically transmissive substrate 120 (e.g., a substrate that enables the transmission of light at various wavelengths) may be optically transmissive to one or more wavelengths of light (e.g., output by a light source, such as a laser) such that electromagnetic radiation passes through the substrate. For instance, a transmittance of the optically transmissive substrate 120 may be greater than some percentage (e.g., greater than about 80 percent, greater than about 85 percent, or greater than about 90 percent) for normal incident light of a wavelength. In other examples, at least a portion of the light output by a light source may be transmitted through the optically transmissive substrate 120. In some examples, the optically transmissive substrate 120 may have a thickness between about 30 micrometers (μm) and about 5 mm, or between about 100 μm and about 5 mm, or between about 100 μm and about 1.5 mm.

The semiconductor substrate 125 may be a silicon-based material (e.g., monocrystalline silicon, silicon, silicon carbide) or another semiconductor type material (e.g., gallium arsenide, lithium tantalum oxide), a chalcogenide glass, or crystalline type material, among other examples. In some examples, the semiconductor substrate 125 may have a thickness between about 40 μm and about 1.5 mm, or between about 50 μm and about 100 μm. In some aspects, the bonded wafer may be referred to as a silicon-on-glass wafer, or other similar terminology.

In some cases, the optically transmissive substrate 120 and/or the semiconductor substrate 125 may comprise other materials and/or coatings. For example, one or both of the optically transmissive substrate 120 or the semiconductor substrate may include different semiconductor materials, different transparent materials, different brittle materials, or any combination thereof. Thus, the example materials described herein should not be considered limiting to the scope covered by the claims or the disclosure.

The optically transmissive substrate 120 and the semiconductor substrate 125 may be coupled together using one or more bonding techniques, such as anodic bonding, adhesive bonding, fusion bonding, hybrid bonding, pressure bonding, chemical bonding, or any combination thereof, among other examples. For example, a surface 121 (e.g., an inner surface, a bottom surface) of the optically transmissive substrate 120 may be coupled with (e.g., bonded with) a surface 126 (e.g., an inner surface, a top surface) of the semiconductor substrate 125. In some cases, bonding the optically transmissive substrate 120 with the semiconductor substrate 125 may form a bonding region 130 between the surface 121 and the surface 126, which may include some material associated with the bonding.

Each laser (e.g., the first laser 105-a, the second laser 105-b) of the system 100 may be configured to output a laser beam for irradiating at least a portion of the bonded substrate for dicing the bonded wafer 115 into multiple dies. That is, the first laser 105-a may output a first laser beam 135-a and the second laser 105-b may output a second laser beam 135-b. Each laser may be an example of or include a pulsed laser (e.g., an ultrashort pulsed laser, a picosecond pulsed laser, a nanosecond pulsed laser, or the like) that is configured to operate at some wavelength of light, λ. For example, the first laser 105-a may be configured to operate at a wavelength between about 500 nanometers (nm) and about 1100 nm, or between about 215 nm and about 1064 nm, among other examples. For instance, the first laser 105-a may be configured to output the first laser beam 135-a at a wavelength of 1064 nm, 1030 nm, 532 nm, 530 nm, 355 nm, 343 nm, 266 nm, 215 nm, among other example wavelengths. In some examples, the first laser 105-a is configured for forming damage tracks 123 in substrate 120 by outputting a first laser beam 135-a having a laser beam focal line with relatively low divergence and relatively weak diffraction (e.g., a non-diffracting laser beam, a quasi-non-diffracting laser beam). Here, the first laser beam 135-a may be an example of a Bessel beam, a Gauss-Bessel beam, an Airy beam, a Weber beam, a Mathieu beam, among other examples of beams with relatively low diffraction. In some aspects, an intensity distribution of the first laser beam 135-a output by the first laser 105-a may be configured (e.g., controlled) for forming the damage tracks 123 in the optically transmissive substrate 120.

Additionally, the second laser 105-b may be configured to operate at a wavelength between about 1000 nm and about 3000 nm, or between about 700 nm and about 1064 nm, among other examples. For example, the second laser 105-b may be configured to output the second laser beam 135-b at a wavelength of 1064 nm. The first laser 105-a and/or the second laser 105-b may be configured to operate at other wavelengths not explicitly mentioned herein. Further, the second laser 105-b may be configured to output the second laser beam 135-b having a Gaussian distribution or other distribution, where a portion (e.g., a center portion) of the distribution is used to form damage regions 127 in substrate 125. In some aspects, the wavelength of the second laser beam 135-b may be configured to achieve maximum absorption within the semiconductor substrate 125 (e.g., to create one or more damage regions 127) may be achieved, for example, via optical focusing (e.g., using the optical components 110-b).

In some aspects, a wavelength of the first laser 105-a and/or the second laser 105-b may be configured for processing the bonded wafer 115. For instance, a respective wavelength, λ, of the first laser 105-a and/or the second laser 105-b may be based on one or more materials of the bonded wafer 115, such that some portion of the bonded wafer 115 (e.g., the optically transmissive substrate 120 or the semiconductor substrate 125, or both) is substantially transparent to the laser light generated by the first laser 105-a and/or the second laser 105-b.

Each laser may generate optical power in multiple pulses (e.g., bursts) with some repetition. Each laser beam pulse may include a burst of multiple sub-pulses, and a duration of a sub-pulse may be some quantity of nanoseconds (ns) in duration, some quantity of femtoseconds (fs) in duration, among other example durations. In some examples, the duration of one pulse (e.g., including the burst of multiple sub-pulses) may be some quantity of microseconds in duration. In some examples, the pulse width of the first laser 105-a may be between about 1 fs and about 200 ps in duration, or between about 10 fs and about 100 ps in duration, among other examples. In some examples, the pulse width of the second laser 105-b may be less than about 500 ns, or between about 10 fs and about 100 ps, among other examples. The first laser 105-a and/or the second laser 105-b may be an example of a mode-locked laser, a Q-switching laser, a pulsed-pumping laser, among other examples, that generates a pulsed output (e.g., a non-continuous output). The first laser 105-a and/or the second laser 105-b, however, may be an example of another type of laser not mentioned herein, and the examples described herein should not be considered limiting to the scope covered by the claims or the disclosure.

The system 100 may include one or more optical components (e.g., optics) associated with each of the lasers, where the one or more optical components may be configured to focus, direct, or modify the respective laser beams output by a laser. For example, the first laser 105-a may generate the first laser beam 135-a, and a first set of optical components 110-a may focus the first laser beam 135-a at, in, or through the optically transmissive substrate 120. Similarly, the second laser 105-b may generate the second laser beam 135-b, and a second set of optical components 110-b may focus the second laser beam 135-b at, in, or through the semiconductor substrate 125. The optical components 110-a and 110-b may include one or more lenses, beam splitters, prisms, mirrors, optical plates, or any combination thereof, among other examples). In some implementations, the system 100 may implement additional optics or optical components, or may implement the optical components within one or more of the respective lasers. In any case, the optical components 110-a and 110-b may be configured to enable a laser to irradiate one or more materials of the bonded wafer 115.

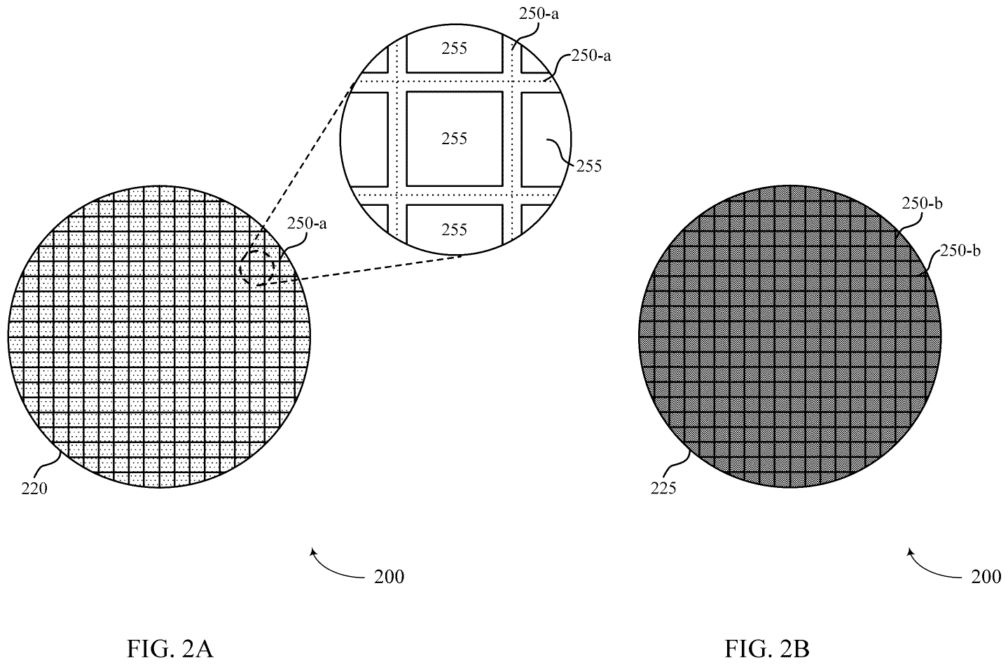

In some examples, one or both of a laser (e.g., the first laser 105-a, the second laser 105-b) or the bonded wafer 115 may be moved or translated during laser processing of the bonded wafer 115. For example, when irradiating the optically transmissive substrate 120 (e.g., to create respective damage tracks 123 in the optically transmissive substrate 120), the first laser 105-a may be laterally translated in one or more directions to create respective contour lines in the optically transmissive substrate 120. Likewise, when irradiating the semiconductor substrate 125 (e.g., to create respective damage regions 127 in the semiconductor substrate 125), the second laser 105-b may be laterally translated to create respective contour lines in the semiconductor substrate 125. Such translation may be performed multiple times to create multiple contour lines, as described with further detail with reference to FIGS. 2A and 2B. Additionally, or alternatively, the bonded wafer 115 may be laterally translated in one or more directions during laser processing to create the contour lines. Such contour lines may enable the bonded wafer 115 to be segmented into respective dies when one or more forces are applied to the bonded wafer 115.

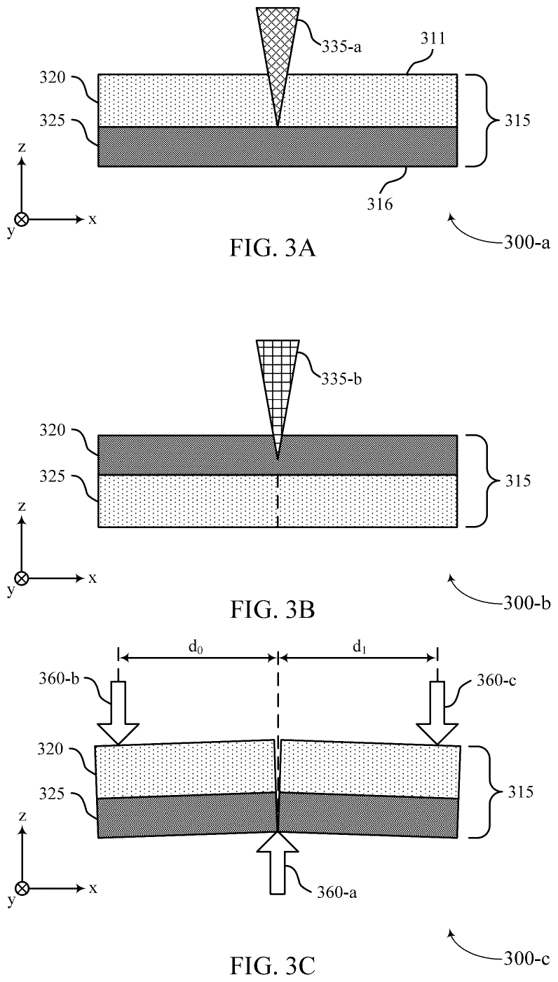

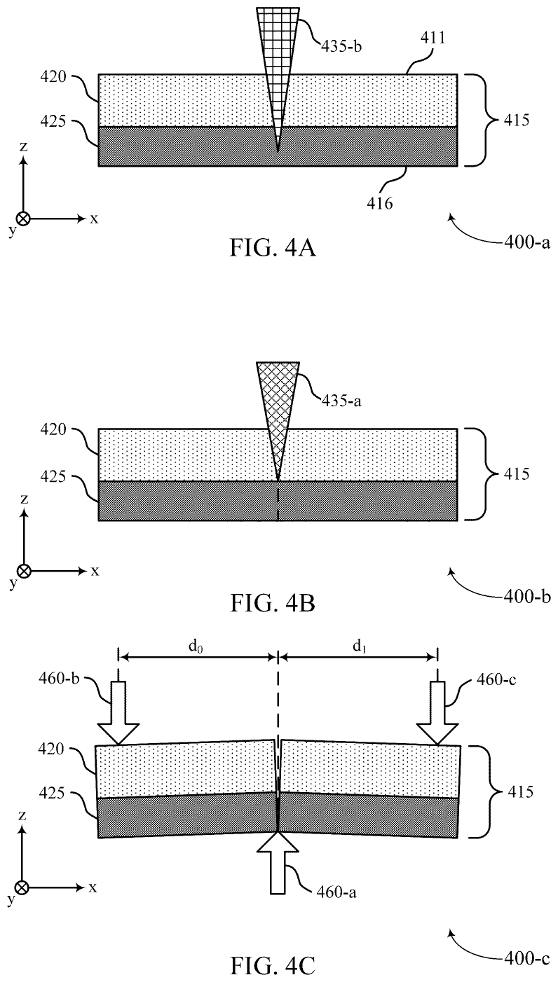

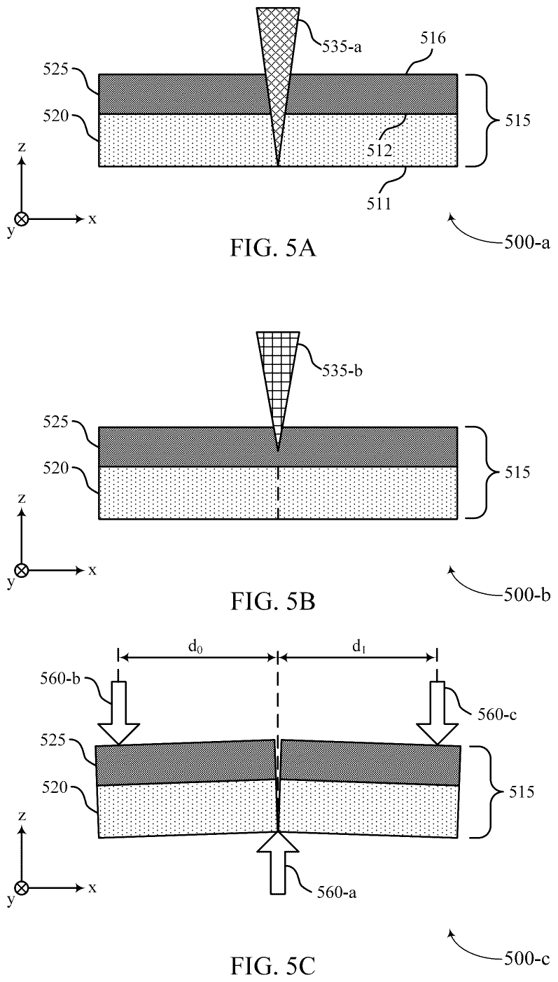

In accordance with the techniques described herein, the first laser 105-a may irradiate a substrate of the bonded wafer 115 (e.g., the optically transmissive substrate 120) using a first laser technology (e.g., nano-perforation) and the second laser 105-b may irradiate another substrate of the bonded wafer 115 (e.g., the semiconductor substrate 125) using a second laser technology (e.g., stealth dicing). Such examples may be described in more detail with reference to FIGS. 3A through 3C. In other examples, the first laser 105-a may irradiate a substrate of the bonded wafer 115 (e.g., the optically transmissive substrate 120) through another substrate of the bonded wafer 115 (e.g., through the semiconductor substrate 125), and the second laser 105-b may irradiate the other substrate of the bonded wafer 115 (e.g., the semiconductor substrate 125) from the same direction as the first laser 105-a. Additionally, or alternatively, a similar method may be applied, where the second laser 105-b may irradiate a substrate of the bonded wafer 115 (e.g., the semiconductor substrate 125) through another substrate of the bonded wafer 115 (e.g., through the optically transmissive substrate 120), and the first laser 105-a may irradiate the other substrate of the bonded wafer 115 (e.g., the optically transmissive substrate 120) from the same direction as the second laser 105-b. These and other examples may be described in more detail with reference to FIGS. 4A through 5C. However, FIG. 1 may depict first laser 105-a directly irradiating the optically transmissive substrate 120 (e.g., using the first laser technology) and the second laser 105-b directly irradiating the semiconductor substrate 125 (e.g., using the second laser technology). Additionally, while FIG. 1 illustrates the irradiation of the bonded wafer 115 using lasers from different directions, the lasers may irradiate the bonded wafer 115 from the same direction (e.g., the bonded wafer 115 may be rotated (e.g., flipped over) to enable respective irradiation of the optically transmissive substrate 120 and the semiconductor substrate 125).

In some cases, the first laser technology may be associated with forming damage tracks 123 through perforation techniques (e.g., nano-perforation techniques). For example, the first laser 105-a may irradiate the optically transmissive substrate 120 using the first laser technology to form nano-perforations in the optically transmissive substrate 120, where each damage track 123 created by the first laser beam 135-a may have a diameter of about 10 μm or less. For example, the first laser beam 135-a may have a diameter between about 0.25 μm and about 10 μm, between about 0.25 μm and about 5 μm, between about 0.25 and about 2.5 μm, between about 0.5 μm and about 10 μm, between about 0.5 μm and about 5 μm, between about 0.5 and about 2.5 μm, between about 0.75 μm and about 10 μm, between about 0.75 μm and about 5 μm, between about 0.75 μm and about 2.5 μm, among other examples. In some such examples, the first laser 105-a may output the first laser beam 135-a toward a surface 122 (e.g., an outer surface, a top surface) of the optically transmissive substrate 120 (e.g., using the optical components 110-a) to at least partially perforate the surface 122. Formation of the damage tracks 123 may include applying a quantity of pulses of the laser beam 135-a to the surface 122, thereby forming damage tracks 123 by perforating the optically transmissive substrate 120. In some aspects, the laser beam 135-a may be configured to generate two or more sub-pulses (e.g., a pulse burst of multiple sub-pulses, a pulse burst of 3 sub-pulses, a pulse burst of 4 sub-pulses, a pulse-burst of 5 sub-pulses, a pulse burst of 10 sub-pulses, a pulse burst of 20 sub-pulses, a pulse burst of between 1 and 30 sub-pulses, a pulse burst of between 5 and 20 sub-pulses, among other examples) used to form the damage tracks 123. The damage tracks 123 may each be a region of modified material (e.g., a region of modified refractive index relative to the bulk material of the optically transmissive substrate 120) that forms a trench, void space, crack, scratch, flaw, hole, perforation, or other deformity in the substrate 120. Each damage track 123 extends to a depth at least partially through the optically transmissive substrate 120 (e.g., in a vertical direction in reference to the orientation of FIG. 1, through some depth of the optically transmissive substrate 120) relative to the surface 122. For example, each pulse, pulse burst, or sub-pulse of the laser beam 135-a may be associated with perforating at least a portion of the optically transmissive substrate 120, forming a damage track 123 in the optically transmissive substrate 120 with a depth at least partially based on a duration (e.g., pulse width) and/or intensity (e.g., wavelength) of the respective pulse, pulse burst, or sub-pulse. Thus, each pulse, pulse burst, or sub-pulse of the laser beam 135-a may be associated with incrementally forming one or multiple damage tracks 123 in the optically transmissive substrate 120. Further, translating the optically transmissive substrate 120, the first laser 105-a, and/or the first laser beam 135-a relative to each other, as discussed above, results in the formation of multiple damage tracks 123 in the substrate 120 that form a first contour line. In some cases, the damage tracks 123 may each extend through the optically transmissive substrate 120 such that the damage tracks 123 may separate the optically transmissive substrate 120 along the first contour line. However, in other cases, as depicted in FIG. 1, the damage tracks 123 may each extend partially through the optically transmissive substrate 120, such that a mechanical force may be involved in separating the optically transmissive substrate 120 along the first contour line. For example, the damage tracks 123 may each have a diameter about 10 μm or smaller, or about 8 μm or smaller, or about 6 μm or smaller. The damage tracks 123 of the optically transmissive substrate 120 may be associated with a relatively reduced resistance to mechanical forces (e.g., bending forces, tensile forces, shear forces) applied to the bonded wafer 115. For example, the damage tracks 123 may create a region along the first contour line that is associated with a relatively high likelihood of fracture propagation under mechanical force.

The second laser technology may be associated with stealth dicing techniques. For example, the second laser 105-b may irradiate the semiconductor substrate 125 using the second laser technology to form damage regions 127 within the semiconductor substrate 125. In some such examples, the second laser 105-b may focus the second laser beam 135-b at least partially within a volume of the semiconductor substrate 125 (e.g., using the optical components 110-b) to form the damage regions 127 within the volume. In some such examples, the damage regions 127 may be formed in one or more layers of the semiconductor substrate 125, with each layer being in a vertical direction in reference to the orientation of FIG. 1, which may be referred to as stealth dicing layers. For example, there may be one layer of damage regions 127, two layers of damage regions 127, three layers of damage regions 127 (as shown in FIG. 1), four layers of damage regions 127, five layers of damage regions 127, among other examples. In some aspects, respective layers including the damage regions 127 may be equidistant from one another through the volume of the semiconductor substrate 125. In some cases, a quantity of layers may be based on a size (e.g., a thickness) of the semiconductor substrate 125. Each damage region 127 may include material that is modified via multiphoton absorption from the second laser beam 135-b, where radiation from the second laser beam 135-b may not affect (or may minimally affect) other portions of the semiconductor substrate 125 outside of the damage regions 127 (e.g., only the damage regions 127 of the semiconductor substrate 125 may be modified (e.g., damaged) by radiation of the second laser beam 135-b). In some aspects, each damage region 127 may include a cavity and a molten volume (e.g., damaged volume) of the semiconductor substrate 125. For example, each pulse of the laser beam 135-b may be associated with creating a relatively small weak point (e.g., crack, stress point, strain point) at a targeted region, forming a damage region 127, a size of which may be at least partially based on a duration (e.g., pulse width) or intensity (e.g., wavelength) of the respective pulse. A damage region 127 may have one or more dimensions of about 10 μm across (e.g., in width or height), or less than about 10 μm across, among other example dimensions. For instance, a damage region 127 created by the second laser technology may be less than 10 μm in diameter, less than 5 μm in diameter, less than 4 μm in diameter, less than 3 μm in diameter, less than 1 μm in diameter, among other examples.

Translating the semiconductor substrate 125, the second laser 105-b, and/or the second laser beam 135-b relative to each other, as discussed above, results in the formation of multiple damage regions 127 in the semiconductor substrate 125 that form a second contour line. The damage regions 127 of the semiconductor substrate 125 may be associated with a relatively weak resistance to mechanical forces (e.g., bending forces, tensile forces, shear forces) applied to the bonded wafer 115 along the second contour line.

Furthermore, a set of damage regions 127 through substrate 125 may be aligned with a set of damage tracks 123 through substrate 120 along a plane 128, as shown in FIG. 1. The first and second contour lines are disposed along plane 128 such that plane 128 is associated with an increased likelihood of fracture (e.g., crack) propagation through the semiconductor substrate 125 and through the optically transmissive substrate 120 when mechanical forces (e.g., bending forces, tensile forces, shear forces) are applied to the bonded wafer. Each plane 128 may correspond to a modification pathway (e.g., a contour line, a modification line) formed in the semiconductor substrate 125 and in the optically transmissive substrate 120 and corresponding to a desired geometry for respective dies formed by segmenting the bonded wafer 115.

As described with reference to FIGS. 3C, 4C, and 5C, after irradiating the substrates of the bonded wafer 115 using the laser technologies described herein, one or more mechanical forces may be applied to the bonded wafer 115 to separate the bonded wafer 115 into the respective dies. For example, the damage tracks 123 and the damage regions 127 may be aligned along the plane 128, thereby enabling the bonded wafer 115 to be separated into the respective dies along the plane 128 (e.g., the damage tracks 123 and the damage regions 127 along the plane 128 may correspond to a contour line that, when the one or more forces are applied to the bonded wafer 115, enable the bonded wafer to be segmented into the dies in accordance with some desired geometry defined by the contour line).

In some aspects, the system 100 may include a single laser (e.g., the first laser 105-a) configured for irradiating the multiple materials (e.g., the optically transmissive substrate 120 and the semiconductor substrate 125) of the bonded wafer 115. In such cases, the first laser 105-a may be configured to adjust one or more parameters to enable irradiation (e.g., damage of) the multiple materials of the bonded wafer 115. As an example, after irradiating and creating damage tracks 123 in the optically transmissive substrate 120, a duration (e.g., a pulse width) and/or a wavelength of the first laser beam 135-a output by the first laser 105-a may be adjusted to create the damage regions 127 in the semiconductor substrate 125 (or vice versa). As such, respective laser beams having different properties may be generated using the same laser source (e.g., either the first laser 105-a or the second laser 105-b) and used to irradiate different materials of the optically transmissive substrate 120 and the semiconductor substrate 125 in accordance with one or more aspects of the techniques described herein. In some implementations, one or more optics (e.g., a set of optical components 110-a) may be configurable or may be modified to enable the single laser to irradiate the bonded wafer 115.

The bonded wafer 115 may be bonded before or after one or both of the optically transmissive substrate 120 or the semiconductor substrate 125 are irradiated. For example, the optically transmissive substrate 120 may be coupled with (e.g., bonded to) the semiconductor substrate 125 using one or more bonding techniques prior to being irradiated using the first laser 105-a and/or the second laser 105-b. In another example, the optically transmissive substrate 120 may first be irradiated (e.g., to create the damage tracks 123 corresponding to contour lines in the optically transmissive substrate 120) by the first laser 105-a. The irradiated optically transmissive substrate 120 may then be bonded to the semiconductor substrate 125, and the semiconductor substrate 125 may then be irradiated by the second laser 105-b after being coupled with the optically transmissive substrate 120 (e.g., to create the damage regions 127 corresponding to contour lines in the semiconductor substrate 125). In some other examples, after the semiconductor substrate 125 is bonded with the irradiated optically transmissive substrate 120, one or more mechanical processes may be applied to the semiconductor substrate 125 to remove a portion of the semiconductor material, thereby damaging the semiconductor substrate 125 for segmentation into multiple dies. Here, the one or more mechanical processes may include sawing (e.g., using a saw blade for removing at least a portion of the semiconductor material) and/or blade scribing (e.g., where only a portion of the material is removed to generate respective contour lines and enabling a relatively reduced resistance to breaking), among other techniques. In some examples, other techniques, such as plasma dicing, may be used after the semiconductor substrate 125 is bonded to the optically transmissive substrate 120 (e.g., and after the optically transmissive substrate 120 is irradiated). After a portion of the material of the semiconductor substrate 125 is modified (e.g., irradiated, mechanically removed), one or more forces may be applied to the bonded wafer 115 including the optically transmissive substrate 120 and the semiconductor substrate 125 to segment the bonded wafer 115 into multiple dies.

Alternatively, the semiconductor substrate 125 may be initially irradiated (e.g., to create the damage regions 127 corresponding to contour lines in the semiconductor substrate 125) using the second laser 105-b, then the semiconductor substrate 125 may be bonded to the optically transmissive substrate 120, and the optically transmissive substrate 120 may be irradiated by the first laser 105-a after being coupled with the semiconductor substrate 125. As similarly described herein, after bonding to the irradiated semiconductor substrate 125, the optically transmissive substrate 120 may be subjected to one or more mechanical processes may be applied to the optically transmissive substrate 120 to remove a portion of the semiconductor material, thereby damaging the optically transmissive substrate 120 for segmentation into multiple dies. Here, the one or more mechanical processes may include sawing (e.g., using a saw blade for removing at least a portion of the optically transmissive material) and/or blade scribing (e.g., where only a portion of the material is removed to generate respective contour lines and enabling a relatively reduced resistance to breaking), among other techniques. In some examples, other techniques, such as plasma dicing, may be used after the optically transmissive substrate 120 is bonded to the semiconductor substrate 125 (e.g., and after the semiconductor substrate 125 is irradiated). In any case, after a portion of the material of the optically transmissive substrate 120 is modified (e.g., irradiated, mechanically removed), one or more forces may be applied to the bonded wafer 115 including the optically transmissive substrate 120 and the semiconductor substrate to segment the bonded wafer 115 into multiple dies.

In yet another example, the optically transmissive substrate 120 may be irradiated by the first laser 105-a (e.g., to create contour lines in the optically transmissive substrate 120), and the semiconductor substrate 125 may be irradiated (e.g., simultaneously or sequentially) by the second laser 105-b (e.g., to create contour lines in the semiconductor substrate 125). Then the optically transmissive substrate 120 and the semiconductor substrate 125 (each having been previously irradiated) may be coupled together, for example, using one or more bonding techniques to create the bonded wafer 115. Following the bonding, one or more forced are applied to the bonded wafer 115 to segment the wafer into multiple dies.

Dicing the bonded wafer 115 using the combination of laser technologies described herein, may be associated with advantageous results for the substrates of the bonded wafer 115. For example, using the first laser technology to form damage tracks 123 (e.g., implemented via nano-perforation techniques) through the optically transmissive substrate 120 may produce a relatively fast, accurate cut through the optically transmissive substrate 120. However, unlike other dicing processes, the first laser technology may not be associated with causing damage or excess material removal to the semiconductor substrate 125. Likewise, using the second laser technology to implement stealth dicing for cutting the semiconductor substrate 125 may produce an accurate separation through the semiconductor substrate 125 without causing damage or excess material removal to the optically transmissive substrate 120. Here, the applier laser technologies may result in a low- or zero-kerf separation (e.g., less than about 200 μm) of the bonded wafer 115 when dicing the wafer into dies. Therefore, implementing the combination of laser technologies as described herein may support accurate dicing of the bonded wafer 115 without adversely affecting the substrates thereof.

FIGS. 2A and 2B show an example of a bonded wafer 200 that supports techniques for dicing bonded wafers using laser technologies in accordance with examples as disclosed herein. The bonded wafer 200 may be an example of a wafer that has been irradiated by one or more lasers in accordance with the techniques described herein, for example, prior to the application of a mechanical force to segment (e.g., break) the wafer into multiple dies. For example, the bonded wafer 200 may be an example of the bonded wafer 115 described with reference to FIG. 1. As such, the bonded wafer 200 may comprise multiple layers, including an optically transmissive substrate layer 220 coupled with (e.g., bonded to) a semiconductor substrate layer 225. The optically transmissive substrate layer 220 and the semiconductor substrate layer 225 may be an example of the optically transmissive substrate 120 and the semiconductor substrate 125, respectively, described with reference to FIG. 1.

As illustrated by FIG. 2A, the optically transmissive substrate layer 220 may be irradiated using a laser beam (e.g., a first laser beam output by a first laser source) resulting in multiple damage tracks formed in the optically transmissive substrate layer 220. Each damage track may extend at least partially through the optically transmissive substrate layer 220 by one or more pulses of the first laser beam. Further, the laser beam and the bonded wafer 200 may be translated with respect to one another, which may create multiple first contour lines 250-a in the optically transmissive substrate layer 220. The first contour lines 250-a may generally correspond to defects or damage in the optically transmissive substrate layer 220 formed by the laser processing techniques described herein (e.g., nano-perforation), and may enable the bonded wafer 200 to be separated (e.g., diced, segmented, singulated) into multiple dies 255 using one or more forces. That is, a first contour line 250-a may be formed in the optically transmissive substrate layer 220 by creating multiple defects (e.g., modified material) in the optically transmissive substrate layer 220 using, for example, a pulsed laser beam at successive locations along the first contour line 250-a. Multiple first contour lines 250-a may be formed in the optically transmissive substrate layer 220 in both the horizontal direction and the vertical direction (e.g., relative to the orientation illustrated by FIG. 2A) by translating the optically transmissive substrate layer 220 relative to the pulsed laser beam. In some aspects, the first contour lines 250-a may be referred to as modification lines, modification paths, modification pathways, or other terminology. Further, one or more of the first contour lines 250-a may be linear or non-linear (e.g., curved), which may be configurable based on a desired geometry of the dies 255 (e.g., after segmentation), a geometry of the wafer 200, or a combination thereof. Thus, the first contour lines 250-a may refer to a series of defects (e.g., relatively closely-spaced regions of modified material, for example, corresponding to respective damage tracks) in the optically transmissive substrate layer 220 formed by translating a laser along some path. In any case, the first contour lines 250-a may correspond to a surface for a desired separation of the optically transmissive substrate layer 220 into the dies 255.

As similarly illustrated by FIG. 2B, the semiconductor substrate layer 225 may be irradiated using a laser beam (e.g., a second laser beam output by the first laser source or by the second laser source) resulting in multiple regions that are damaged by the laser beam (e.g., that is focused in a volume of the semiconductor substrate layer 225). The regions damaged by the laser beam may correspond to one or more layers of damage caused by the laser beam, which may extend at least partially through the semiconductor substrate layer 225. When processing the semiconductor substrate layer 225, the laser beam and the bonded wafer 200 may be translated with respect to one another, resulting in multiple second contour lines 250-b in the semiconductor substrate layer 225. The second contour lines 250-b in the semiconductor substrate layer 225 may correspond to defects or damage in the semiconductor substrate layer 225 formed by the laser processing techniques described herein (e.g., stealth dicing), and may enable the bonded wafer 200 to be separated (e.g., diced, segmented, singulated) into multiple dies 255 using one or more forces. In particular, a second contour line 250-b may be formed in the semiconductor substrate layer 225 by creating multiple defects (e.g., modified material) in the semiconductor substrate layer 225 using, for example, a pulsed laser beam focused within a volume of the semiconductor substrate layer 225 and at successive locations along the second contour line 250-b. Multiple second contour lines 250-b may be formed in the semiconductor substrate layer 225 in both the horizontal direction and the vertical direction (e.g., relative to the orientation illustrated by FIG. 2B) by translating the semiconductor substrate layer 225 relative to the pulsed laser beam. The second contour lines 250-b may be referred to as modification lines, modification paths, modification pathways, or other terminology. One or more of the second contour lines 250-b may be linear or non-linear (e.g., curved), which may be configurable based on a desired geometry of the dies 255 (e.g., after segmentation), a geometry of the wafer 200, or a combination thereof. As such, the second contour lines 250-b may refer to a series of defects (e.g., relatively closely-spaced regions of modified material, for example, corresponding to respective damage regions) in the semiconductor substrate layer 225 formed by translating a laser along some path. The second contour lines 250-b may correspond to a surface for a desired separation of the semiconductor substrate layer 225 into the dies 255.

The first contour lines 250-a and the second contour lines 250-b formed on the optically transmissive substrate layer 220 and the semiconductor substrate layer 225 may be aligned such that, when the bonded wafer 200 is segmented, each die 255 is formed having multiple relatively planar surfaces with minimal or no defects (e.g., limited or no chopping, limited or no cracking). Such alignment may be achieved via visual alignment, for example, using two or more fiducials (e.g., visible on both sides of the bonded wafer 200), using a trace from a previous laser process (e.g., damage previously caused by the first laser beam or the second laser beam), or any combination thereof, among other examples. Each die 255 corresponds to some functional area of the bonded wafer 200, and may be referred to as a functional sub-unit of the wafer 200. In some examples, each die 255 may be associated with a same function or a different function, where respective functions may be associated with, for example, chips (e.g., microchips), circuits, optics, filamentation, or other functional structures or components, among other examples. In addition, while the dies 255 are illustrated as having a rectangular shape, it is noted that each die 255 may be formed to have one or more different shapes, and the examples described and illustrated herein should not be considered limiting to the scope of the claims or description.

The described techniques for dicing the bonded wafer 200 using multiple laser technologies may enable more efficient utilization of an area of the bonded wafer 200. For example, through the use of nano-perforation and stealth dicing techniques to form the first contour lines 250-a and the second contour lines 250-b, respectively, relatively less material may be removed from either the optically transmissive substrate layer 220 or the semiconductor substrate layer 225 (e.g., as compared to other techniques, such as blade dicing and others). As such, dies 255 with relatively greater dimensions may be possible. Additionally, or alternatively, respective dies 255 may support surface features or components (e.g., electrical components) separated by relatively less distance when the bonded wafer 200 is segmented using the laser technologies described herein, which enable for low-kerf separation of the dies 255.

FIGS. 3A, 3B, and 3C show examples of processing steps 300-a, 300-b, and 300-c that support techniques for dicing bonded wafers using laser technologies in accordance with examples as disclosed herein. The processing steps 300-a, 300-b, 300-c may illustrate aspects of a sequence of manufacturing operations for fabricating aspects of a bonded wafer 315, which may be an example of a bonded wafer 115 and a bonded wafer 200, as described with reference to FIGS. 1, 2A, and 2B. As such, the bonded wafer 315 may be segmented (e.g., diced) into multiple dies using a system and/or apparatus, such as the system 100 described with reference to FIG. 1. The processing steps 300-a, 300-b, and 300-c may be an example of performing nano-perforation from a first side of the bonded wafer 315 corresponding to an optically transmissive substrate 320, followed by performing stealth dicing from another side of the bonded wafer 315 corresponding to a semiconductor substrate 325.

For illustrative purposes, aspects of the processing steps 300-a, 300-b, and 300-c may be described with reference to an x-direction, a y-direction, and a z-direction of the illustrated coordinate system. For example, the processing steps 300-a, 300-b, and 300-c may illustrate various cross-sectional views of a bonded wafer 315 in an xz-plane. In some examples, the z-direction may be illustrative of a direction orthogonal to a surface (e.g., a surface in an xy-plane) of the bonded wafer 315, and each of the related regions, illustrated by their respective cross section in the xz-plane, may extend for some distance along the y-direction. Although the processing steps 300-a, 300-b, and 300-c illustrate examples of relative dimensions and quantities of various features, aspects of the bonded wafer 315 may be implemented with other relative dimensions or quantities of such features in accordance with examples as disclosed herein. In the following description of the processing steps 300-a, 300-b, and 300-c, some methods, techniques, processes, and operations may be performed in different orders or at different times. Further, some operations may be left out of the processing steps 300-a, 300-b, and 300-c, or other operations may be added to the processing steps 300-a, 300-b, and 300-c. The processing steps 300-a, 300-b, and 300-c may illustrate operations for dicing the bonded wafer 315 by irradiating respective substrates of the bonded wafer 315 using multiple (e.g., two) laser technologies and separating the bonded wafer 315 by applying mechanical force to the substrates.

Operations illustrated in and described with reference to FIGS. 3A through 3C may be performed by a system, which may be an example of a system 100, as described with reference to FIG. 1. Additionally, or alternatively, operations illustrated in and described with reference to FIGS. 3A through 3C may be performed by a manufacturing system, such as a semiconductor fabrication system configured to perform additive operations such as bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

In some cases, an optically transmissive substrate 320 of the bonded wafer 315 may be bonded with a semiconductor substrate 325 of the bonded wafer 315, which may be examples of an optically transmissive substrate 120 and a semiconductor substrate 125, as described with reference to FIG. 1, respectively, as well as the optically transmissive substrate layer 220 and the semiconductor substrate layer 225 described with reference to FIGS. 2A and 2B, respectively. The optically transmissive substrate 320 and the semiconductor substrate 325 may be bonded together using anodic bonding, adhesive bonding, fusion bonding, hybrid bonding, pressure bonding, chemical bonding, or any combination thereof, among other examples. In some examples, the optically transmissive substrate 320 and the semiconductor substrate 325 may be bonded prior to or after performing the processing step 300-a, 300-b, or 300-c.

In some cases, the bonded wafer 315 may be subjected to one or more processes for reducing a total thickness (e.g., thinning) of the bonded wafer 315 (e.g., in the z-direction), which may include removing a portion of the optically transmissive substrate 320 or a portion of the semiconductor substrate 325, or a combination thereof. For example, a surface 311 (e.g., an outer surface) of the optically transmissive substrate 320 may be subjected to one or more removal processes to reduce (e.g., decrease) a thickness of the optically transmissive substrate 320, including reducing the surface 311 to a depth that at least partially extends into the optically transmissive substrate 320. Similarly, a surface 316 (e.g., an outer surface) of the semiconductor substrate 325 may be subjected to one or more removal processes to reduce a thickness of the semiconductor substrate 325, including reducing the surface 316 to a depth that at least partially extends into the semiconductor substrate 325. In some examples, the bonded wafer 315 may be thinned prior to or after performing the processing step 300-a, 300-b, or 300-c.

FIG. 3A illustrates a first processing step 300-a for irradiating the optically transmissive substrate 320. The first processing step 300-a may include irradiating the optically transmissive substrate 320 using a first laser technology which may be associated with nano-perforation techniques. For example, a laser (e.g., not shown, which may be an example of the first laser 105-a, as described with reference to FIG. 1) may irradiate the optically transmissive substrate 320 by applying a laser beam 335-a (e.g., directed through one or more optics) to the optically transmissive substrate 320 in a first direction (e.g., opposite the z-direction) to perforate the optically transmissive substrate 320.

Perforating the optically transmissive substrate 320 may include applying a quantity of pulses (or pulse bursts including two or more sub-pulses) of the laser beam 335-a to the surface 311, thereby forming damage tracks in the optically transmissive substrate 320. The damage tracks may form contour lines (e.g., the first contour lines 250-a described with reference to FIG. 2A) extending along the y-direction and extending to a depth (e.g., in the z-direction) at least partially through the optically transmissive substrate 320 relative to the surface 311. In some cases, the damage tracks may extend through the optically transmissive substrate 320. However, in other cases, the damage tracks may extend partially through the optically transmissive substrate 320, such that one or more forces (e.g., bending forces, tensile forces, shear forces) may be involved in separating the optically transmissive substrate 320. The damage tracks formed in the optically transmissive substrate 320 may be associated with a relatively weak resistance to mechanical forces (e.g., bending forces, tensile forces, shear forces) applied to the bonded wafer 315. For example, the damage tracks may create a region associated with a relatively high likelihood of fracture propagation during application of one or more forces (e.g., bending forces, tensile forces, shear forces).

FIG. 3B illustrates a second processing step 300-b for irradiating the semiconductor substrate 325. The second processing step 300-b may include irradiating the semiconductor substrate 325 using a second laser technology which may be associated with stealth dicing techniques. For example, a laser (e.g., not shown, which may be an example of the second laser 105-b, as described with reference to FIG. 1) may irradiate the semiconductor substrate 325 by applying a laser beam 335-b (e.g., directed through one or more optics) to the semiconductor substrate 325 to form damage regions at specific (e.g., targeted) regions within a volume of the semiconductor substrate 325. In some cases, the laser beam 335-b may be applied to the semiconductor substrate 325 in a first direction (e.g., opposite the z-direction), for example, after flipping the bonded wafer 315 over, which may include removing the bonded wafer and reversing an orientation of the bonded wafer 315 as illustrated in FIG. 3B. In other cases, the laser beam 335-b may be applied to the semiconductor substrate 325 in a second direction (e.g., along the z-direction) without flipping the bonded wafer 315. In some cases, the laser beam 335-b may be aligned (e.g., in the x-direction) to the contour lines associated with the damage regions formed from irradiating the optically transmissive substrate 320, at processing step 300-a. In other cases, the laser beam 335-b may be aligned to the damage tracks formed from irradiating the optically transmissive substrate 320 based on visually aligning with two or more fiducials.

In some examples, forming the damage regions within the semiconductor substrate 325 may include focusing the laser beam 335-b at least partially within a volume of the semiconductor substrate 325 (e.g., using one or more optics). In some such examples, the damage regions may correspond to internal layers (e.g., along the x-direction and arranged in the z-direction) of the semiconductor substrate 325 (e.g., not shown) that have been undergone multiphoton absorption via the focused laser beam 335-b. The damage regions may correspond to contour lines (e.g., the second contour lines 250-b described with reference to FIG. 2B) extending along the y-direction and extending to a depth (e.g., in the z-direction) at least partially through the semiconductor substrate 325. The damage regions of the semiconductor substrate 325 may be associated with a relatively weak resistance to one or more mechanical forces (e.g., bending forces, tensile forces, shear forces) applied to the bonded wafer 315. For example, the damage regions may create a plane through the internal layers of the semiconductor substrate 325 which may be associated with an increased likelihood of fracture propagation through the semiconductor substrate 325 when applying one or more mechanical forces (e.g., bending forces, tensile forces, shear forces).

FIG. 3C illustrates a third processing step 300-c for applying one or more forces to the bonded wafer 315. The third processing step 300-c may include applying one or more mechanical forces to one or more of the substrates (e.g., the optically transmissive substrate 320, the semiconductor substrate 325) of the bonded wafer 315 to separate the bonded wafer 315 into respective dies (e.g., the dies 255 described with reference to FIG. 2A). For example, as depicted in FIG. 3C, mechanical forces 360-b and 360-c may be applied to the optically transmissive substrate 320 (e.g., to surface 311), and a mechanical force 360-a may be applied to the semiconductor substrate 325 (e.g., to surface 316). In some aspects, the mechanical force 360-b and the mechanical force 360-c may be applied at a location adjacent to a contour line (e.g., a contour line corresponding to the damage regions and the damage tracks in the respective substrates). The respective locations of the mechanical force 360-b and the mechanical force 360-c may be some distance away from a contour line, where the distance is sufficient to bend and break both the optically transmissive substrate 320 and the semiconductor substrate 325 (e.g., to achieve a desired geometry corresponding to the contour line) with the application of the mechanical force 360-a, the mechanical force 360-b, and the mechanical force 360-c. Here, the distance of the mechanical force 360-b from the damage tracks and/or damage regions (e.g., d₀) and the distance of the mechanical force 360-c from the damage tracks and/or damage regions (e.g., d₁) may be about 10 μm, about 20 μm, about 25 μm, about 40 μm, about 45 μm, among other examples. The distance of the mechanical force 360-b and/or the mechanical force 360-c from the damage track and the damage regions may be based on one or more dimensions of the bonded wafer 315. A magnitude of each of the mechanical forces 360-a, 360-b, and 360-c may be configured to exceed the respective break resistance of the optically transmissive substrate 320 and the semiconductor substrate 325 (e.g., along a contour line). In some aspects, each of the mechanical forces 360-a, 360-b, and 360-c may be equal, or the mechanical forces 360-a, 360-b, and 360-c may be different.

In other examples, the bonded wafer 315 may be secured to a bending component, which may apply a mechanical force along one of the substrates of the bonded wafer 315. In some examples, the optically transmissive substrate 320 or the semiconductor substrate 325 may be held in tension (e.g., one or more tensile forces may be applied) during the process to break the bonded wafer 315 (e.g., when the mechanical forces 360-a, 360-b and 360-c are applied), which may enable enhanced separation of the dies. In some aspects one or more tapes, films, or covers, for the optically transmissive substrate 320 and/or the semiconductor substrate 325 may be used to enable the application of the tensile force.

The forces applied to the bonded wafer to segment the dies may thus be examples of tensile forces, bending forces, shear forces, compression forces, or a combination thereof, among other examples. Applying the mechanical forces may produce a bending stress within the bonded wafer 315 such that the damage tracks of the optically transmissive substrate 320 and the damage regions of the semiconductor substrate 325 may experience rapid crack propagation (e.g., fracture), thereby separating the bonded wafer 315. Due to the alignment of the damage tracks of the optically transmissive substrate 320 and the damage regions of the semiconductor substrate 325, the bonded wafer 315 may be accurately separated along a yz-plane.

Dicing the bonded wafer 315 using the combination of laser technologies as described herein, may be associated with advantageous results for the substrates of the bonded wafer 315. For example, using the first laser technology to implement nano-perforation through the optically transmissive substrate 320 may produce a relatively fast, accurate cut through the optically transmissive substrate 320. However, unlike other dicing processes, the first laser technology may not be associated with causing damage or accidental material removal to the semiconductor substrate 325. Likewise, using the second laser technology to implement stealth dicing for cutting the semiconductor substrate 325 may produce an accurate separation through the semiconductor substrate 325 without causing damage to or excess material removal from the optically transmissive substrate 320. Therefore, implementing the combination of laser technologies as described herein may support accurate dicing for the bonded wafer 315 without adversely affecting the substrates thereof.

FIGS. 4A, 4B, and 4C show examples of processing steps 400-a, 400-b, and 400-c that support techniques for dicing bonded wafers using laser technologies in accordance with examples as disclosed herein. The processing steps 400-a, 400-b, and 400-c may illustrate aspects of a sequence of manufacturing operations for fabricating aspects of a bonded wafer 415, which may be an example of a bonded wafer 115 and a bonded wafer 200, as described with reference to FIGS. 1, 2A, and 2B. The bonded wafer 415 may be segmented (e.g., diced) into multiple dies using a system and/or apparatus, such as the system 100 described with reference to FIG. 1. The processing steps 400-a, 400-b, and 400-c may be an example of performing stealth dicing through a first side of the bonded wafer 415 corresponding to an optically transmissive substrate 420 (e.g., to damage a semiconductor substrate 425), followed by performing nano-perforation from the same side of the bonded wafer 415 to perforate the optically transmissive substrate 420.

For illustrative purposes, aspects of the bonded wafer 415 may be described with reference to an x-direction, a y-direction, and a z-direction of the illustrated coordinate system. For example, the processing steps 400-a, 400-b, and 400-c may illustrate various cross-sectional views of the bonded wafer 415 in an xz-plane. In some examples, the z-direction may be illustrative of a direction orthogonal to a surface (e.g., a surface in an xy-plane) of the bonded wafer 415, and each of the related regions, illustrated by their respective cross section in the x-plane, may extend for some distance along the y-direction. Although the processing steps 400-a, 400-b, and 400-c illustrate examples of relative dimensions and quantities of various features, aspects of the bonded wafer 415 may be implemented with other relative dimensions or quantities of such features in accordance with examples as disclosed herein. In the following description of the processing steps 400-a, 400-b, and 400-c, some methods, techniques, processes, and operations may be performed in different orders or at different times. Further, some operations may be left out of the processing steps 400-a, 400-b, and 400-c, or other operations may be added to the processing steps 400-a, 400-b, and 400-c. The processing steps 400-a, 400-b, and 400-c may illustrate operations for dicing the bonded wafer 415 by irradiating substrates of the bonded wafer 415 using two laser technologies and separating the bonded wafer 415 by applying mechanical force to the substrates.

Operations illustrated in and described with reference to FIGS. 4A through 4C may be performed by a system, which may be an example of a system 100, as described with reference to FIG. 1. Additionally, or alternatively, operations illustrated in and described with reference to FIGS. 4A through 4C may be performed by a manufacturing system, such as a semiconductor fabrication system configured to perform additive operations such as bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

In some cases, an optically transmissive substrate 420 of the bonded wafer 415 may be bonded with a semiconductor substrate 425 of the bonded wafer 415, which may be examples of an optically transmissive substrate 120 and a semiconductor substrate 125, as described with reference to FIG. 1, respectively. Likewise, the optically transmissive substrate 420 may be an example of the optically transmissive substrate layer 220 described with reference to FIG. 2A, and the semiconductor substrate 425 may be an example of the semiconductor substrate layer 225 described with reference to FIG. 2B. The optically transmissive substrate 420 and the semiconductor substrate 425 may be bonded together using anodic bonding, adhesive bonding, fusion bonding, hybrid bonding, pressure bonding, chemical bonding, or any combination thereof, among other examples. In some examples, the optically transmissive substrate 420 and the semiconductor substrate 425 may be bonded prior to or after performing the processing step 400-a, 400-b, or 400-c.

In some cases, the bonded wafer 415 may be subjected to one or more processes for reducing a total thickness (e.g., thinning) of the bonded wafer 415 (e.g., in the z-direction), which may include removing a portion of the optically transmissive substrate 420 or a portion of the semiconductor substrate 425, or a combination thereof. For example, a surface 411 (e.g., an outer surface) of the optically transmissive substrate 420 may be subjected to one or more removal processes to reduce a thickness of the optically transmissive substrate 420, including reducing the surface 411 to a depth that at least partially extends into the optically transmissive substrate 420. Similarly, a surface 416 (e.g., an outer surface) of the semiconductor substrate 425 may be subjected to one or more removal processes to reduce a thickness of the semiconductor substrate 425, including reducing the surface 416 to a depth that at least partially extends into the semiconductor substrate 425. In some examples, the bonded wafer 415 may be thinned prior to or after performing the processing step 400-a, 400-b, or 400-c.

FIG. 4A illustrates a first processing step 400-a for irradiating the semiconductor substrate 425. The first processing step 400-a may include irradiating the semiconductor substrate 425 using a second laser technology which may be associated with stealth dicing techniques. For example, a laser (e.g., not shown, which may be an example of a second laser 105-b, as described with reference to FIG. 1) may irradiate the semiconductor substrate 425 by applying a laser beam 435-b (e.g., using one or more optics) to the semiconductor substrate 425 to form damage regions at various regions within a volume of the semiconductor substrate 425. In some cases, the laser beam 435-b may be applied to the semiconductor substrate 425 in a first direction (e.g., opposite the z-direction) through the optically transmissive substrate 420, based on the optically transmissive substrate 420 being optically transmissive to a wavelength associated with the laser beam 435-b.

In some examples, forming the damage regions within the semiconductor substrate 425 may include focusing the laser beam 435-b at least partially within a volume of the semiconductor substrate 425 (e.g., using one or more optics). In some such examples, the targeted regions may correspond to internal layers (e.g., along the x-direction and arranged in the z-direction) of the semiconductor substrate 425 (e.g., not shown). The damage regions may correspond to contour lines (e.g., the second contour lines 250-b described with reference to FIG. 2B) extending along the y-direction and extending to a depth (e.g., in the z-direction) at least partially through the semiconductor substrate 425. The damage regions of the semiconductor substrate 425 may be associated with a relatively weak resistance to one or more mechanical forces (e.g., bending forces, tensile forces, shear forces) applied to the bonded wafer 415. For example, the damage regions may create a plane through the internal layers of the semiconductor substrate 425 which may be associated with an increased likelihood of fracture propagation through the semiconductor substrate 425 when applying one or more forces (e.g., bending forces, tensile forces, shear forces).

FIG. 4B illustrates a second processing step 400-b for irradiating the optically transmissive substrate 420. The second processing step 400-b may include irradiating the optically transmissive substrate 420 using a first laser technology which may be associated with nano-perforation techniques. For example, a laser (e.g., not shown, which may be an example of the first laser 105-a, as described with reference to FIG. 1) may irradiate the optically transmissive substrate 420 by applying a laser beam 435-a (e.g., using one or more optics) to the optically transmissive substrate 420 in the first direction to perforate the optically transmissive substrate 420 and form damage tracks. In some cases, the laser beam 435-a may be aligned (e.g., in the x-direction) to the damage tracks formed from irradiating the semiconductor substrate 425, at processing step 400-a. In other cases, the laser beam 435-a may be aligned to the damage regions formed from irradiating the semiconductor substrate 425 based on visually aligning with two or more fiducials.

Perforating the optically transmissive substrate may include applying a quantity of pulses of the laser beam 435-a to the surface 411, thereby forming damage tracks in the optically transmissive substrate 420. The damage tracks may correspond to contour lines (e.g., the first contour lines 250-a described with reference to FIG. 2A) extending along the y-direction and extending to a depth (e.g., in the z-direction) at least partially through the optically transmissive substrate 420 relative to the surface 411. In some cases, the damage tracks may extend through the optically transmissive substrate 420. However, in other cases, the damage tracks may extend partially through the optically transmissive substrate 420, such that one or more mechanical forces (e.g., bending forces, tensile forces, shear forces) may be involved in separating the optically transmissive substrate 420. The damage tracks of the optically transmissive substrate 420 may be associated with a relatively weak resistance to forces (e.g., bending forces, tensile forces, shear forces) applied to the bonded wafer 415. For example, the damage tracks may create a region associated with a relatively high likelihood of fracture propagation during application of one or more forces (e.g., bending forces, tensile forces, shear forces).

FIG. 4C illustrates a third processing step 400-c for applying one or more forces to the bonded wafer 415 to segment the bonded wafer 415 into multiple dies. The third processing step 400-c may include applying one or more forces to one or more of the substrates (e.g., the optically transmissive substrate 420, the semiconductor substrate 425) of the bonded wafer 415 to separate the bonded wafer 415 into respective dies. For example, as depicted in FIG. 4C, mechanical forces 460-b and 460-c may be applied to the optically transmissive substrate 420 (e.g., to surface 411), and a mechanical force 460-a may be applied to the semiconductor substrate 425 (e.g., to surface 416). The mechanical force 460-b and the mechanical force 460-c may be applied at a location adjacent to a contour line (e.g., a contour line corresponding to the damage regions and the damage tracks in the respective substrates). The respective locations of the mechanical force 460-b and the mechanical force 460-c may be some distance away from a contour line, where the distance is sufficient to bend and break both the optically transmissive substrate 420 and the semiconductor substrate 425 (e.g., to achieve a desired geometry corresponding to the contour line) with the application of the mechanical force 460-a, the mechanical force 460-b, and the mechanical force 460-c. Here, the distance of the mechanical force 460-b from the damage tracks and/or damage regions (e.g., d₀) and the distance of the mechanical force 460-c from the damage tracks and/or damage regions (e.g., d₁) may be about 10 μm, about 20 μm, about 25 μm, about 40 μm, about 45 μm, among other examples. The distance of the mechanical force 460-b and/or the mechanical force 460-c from the damage track and the damage regions may be based on one or more dimensions of the bonded wafer 415. A magnitude of each of the mechanical forces 460-a, 460-b, and 460-c may be configured to exceed the respective break resistance of the optically transmissive substrate 420 and the semiconductor substrate 425 (e.g., along a contour line). In some aspects, each of the mechanical forces 460-a, 460-b, and 460-c may be equal, or the mechanical forces 460-a, 460-b, and 460-c may be different.

In other examples, the bonded wafer 415 may be secured to a bending component, which may apply a mechanical force along one of the substrates of the bonded wafer 415. The one or more forces applied to the bonded wafer 415 may be examples of tensile forces, bending forces, shear forces, compression forces, or a combination thereof, among other examples. As described herein, one or more tensile forces may be applied to one or both of the optically transmissive substrate 420 or the semiconductor substrate 425. Applying the mechanical forces may produce a bending stress within the bonded wafer 415 such that the damage tracks of the optically transmissive substrate 420 and the damage regions of the semiconductor substrate 425 may experience rapid crack propagation (e.g., fracture), thereby separating the bonded wafer 415. Due to the alignment of the damage tracks of the optically transmissive substrate 420 and the damage regions of the semiconductor substrate 425, the bonded wafer 415 may be accurately separated along a yz-plane.

FIGS. 5A, 5B, and 5C show examples of processing steps 500-a, 500-b, and 500-c that support techniques for dicing bonded wafers using laser technologies in accordance with examples as disclosed herein. The processing steps 500-a, 500-b, and 500-c may illustrate aspects of a sequence of manufacturing operations for fabricating aspects of a bonded wafer 515, which may be an example of a bonded wafer 115 and a bonded wafer 200, as described with reference to FIGS. 1, 2A, and 2B. In such cases, the bonded wafer 515 may be segmented (e.g., diced) into multiple dies using a system and/or apparatus, such as the system 100 described with reference to FIG. 1. The processing steps 500-a, 500-b, and 500-c may be an example of performing stealth dicing through a first side of the bonded wafer 515 corresponding to a semiconductor substrate 525 (e.g., to perforate an optically transmissive substrate 520), followed by performing stealth dicing from the same side of the bonded wafer 515 to damage the semiconductor substrate 525.

For illustrative purposes, aspects of the bonded wafer 515 may be described with reference to an x-direction, a y-direction, and a z-direction of the illustrated coordinate system. For example, the processing steps 500-a, 500-b, and 500-c may illustrate various cross-sectional views of the bonded wafer 515 in an xz-plane. In some examples, the z-direction may be illustrative of a direction orthogonal to a surface (e.g., a surface in an xy-plane) of the bonded wafer 515, and each of the related regions, illustrated by their respective cross section in the xz-plane, may extend for some distance along the y-direction. Although the processing steps 500-a, 500-b, and 500-c illustrate examples of relative dimensions and quantities of various features, aspects of the bonded wafer 515 may be implemented with other relative dimensions or quantities of such features in accordance with examples as disclosed herein. In the following description of the processing steps 500-a, 500-b, and 500-c, some methods, techniques, processes, and operations may be performed in different orders or at different times. Further, some operations may be left out of the processing steps 500-a, 500-b, and 500-c, or other operations may be added to the processing steps 500-a, 500-b, and 500-c. The processing steps 500-a, 500-b, and 500-c may illustrate operations for dicing the bonded wafer 515 by irradiating substrates of the bonded wafer 515 using two laser technologies and separating the bonded wafer 515 by applying mechanical force to the substrates.

Operations illustrated in and described with reference to FIGS. 5A through 5C may be performed by a system, which may be an example of a system 100, as described with reference to FIG. 1. Additionally, or alternatively, operations illustrated in and described with reference to FIGS. 5A through 5C may be performed by a manufacturing system, such as a semiconductor fabrication system configured to perform additive operations such as bonding, subtractive operations such as etching, trenching, planarizing, or polishing, and supporting operations such as masking, patterning, photolithography, or aligning, among other operations that support the described techniques. In some examples, operations performed by such a manufacturing system may be supported by a process controller or its components as described herein.

In some cases, an optically transmissive substrate 520 of the bonded wafer 515 may be bonded with a semiconductor substrate 525 of the bonded wafer 515, which may be examples of an optically transmissive substrate 120 and a semiconductor substrate 125, as described with reference to FIG. 1, respectively. Further, the optically transmissive substrate 520 may be an example of the optically transmissive substrate layer 220 described with reference to FIG. 2A, and the semiconductor substrate 525 may be an example of the semiconductor substrate layer 225 described with reference to FIG. 2B. The optically transmissive substrate 520 and the semiconductor substrate 525 may be coupled (e.g., bonded together) using anodic bonding, adhesive bonding, fusion bonding, hybrid bonding, pressure bonding, chemical bonding, or any combination thereof, among other bonding techniques. In some examples, the optically transmissive substrate 520 and the semiconductor substrate 525 may be bonded either prior to or after performing the processing step 500-a, 500-b, and 500-c.

In some cases, the bonded wafer 515 may be subjected to one or more processes for reducing a total thickness (e.g., thinning) of the bonded wafer 515 (e.g., in the z-direction), which may include removing some portion of the optically transmissive substrate 520 or a portion of the semiconductor substrate 525, or both. For example, a surface 511 (e.g., an outer surface) of the optically transmissive substrate 520 may be subjected to one or more removal processes to reduce a thickness of the optically transmissive substrate 520, including reducing the surface 511 to a depth that at least partially extends into the optically transmissive substrate 520. Similarly, a surface 516 (e.g., an outer surface) of the semiconductor substrate 525 may be subjected to one or more removal processes to reduce a thickness of the semiconductor substrate 525, including reducing the surface 516 to a depth that at least partially extends into the semiconductor substrate 525. In some examples, the bonded wafer 515 may be thinned prior to or after performing the processing step 500-a, 500-b, and 500-c.

FIG. 5A illustrates a first processing step 500-a for irradiating the optically transmissive substrate 520. The first processing step 500-a may include irradiating the optically transmissive substrate 520 using a first laser technology which may be associated with nano-perforation techniques. For example, a laser (e.g., not shown, which may be an example of the first laser 105-a, as described with reference to FIG. 1) may irradiate the optically transmissive substrate 520 by applying a laser beam 535-a (e.g., using one or more optics) to the optically transmissive substrate 520 in a first direction (e.g., opposite the z-direction) to perforate the optically transmissive substrate 520. In some cases, the laser beam 535-a may be applied to the optically transmissive substrate 520 in the first direction through the semiconductor substrate 525, based on the semiconductor substrate 525 being optically transmissive to a wavelength associated with the laser beam 535-a.

Perforating the optically transmissive substrate may include applying a quantity of pulses of the laser beam 535-a to the surface 512, thereby forming damage tracks in the optically transmissive substrate 520. The damage tracks may be contour lines (e.g., the first contour lines 250-a described with reference to FIG. 2A) extending along the y-direction and extending to a depth (e.g., in the z-direction) at least partially through the optically transmissive substrate 520 relative to the surface 512. In some cases, the damage tracks may extend through the optically transmissive substrate 520 such that the damage tracks may separate the optically transmissive substrate 520. However, in other cases, the damage tracks may extend partially through the optically transmissive substrate 520, such that one or more forces (e.g., bending forces, tensile forces, shear forces) may be involved in separating the optically transmissive substrate 520. The damage tracks of the optically transmissive substrate 520 may be associated with a relatively weak resistance to forces (e.g., bending forces, tensile forces, shear forces) applied to the bonded wafer 515. For example, the damage tracks may create a region associated with a relatively high likelihood of fracture propagation when applying one or more forces (e.g., bending forces, tensile forces, shear forces).

FIG. 5B illustrates a second processing step 500-b for irradiating the semiconductor substrate 525. The second processing step 500-b may include irradiating the semiconductor substrate 525 using a second laser technology which may be associated with stealth dicing techniques. For example, a laser (e.g., not shown, which may be an example of a second laser 105-b, as described with reference to FIG. 1) may irradiate the semiconductor substrate 525 by applying a laser beam 535-b (e.g., using one or more optics) to the semiconductor substrate 525 to form damage regions within the semiconductor substrate 525. In some cases, the laser beam 535-b may be applied to the semiconductor substrate 525 in the first direction. In some examples, the laser beam 535-b may be aligned (e.g., in the x-direction) to the contour lines associated with the damage tracks formed from irradiating the optically transmissive substrate 520, at processing step 500-a. In other examples, the laser beam 535-b may be aligned to the damage tracks formed from irradiating the optically transmissive substrate 520 based on visual alignment with two or more fiducials.

In some examples, forming the damage regions within the semiconductor substrate 525 may include focusing the laser beam 535-b at least partially within a volume of the semiconductor substrate 525 (e.g., using one or more optics). In some such examples, the targeted regions may correspond to internal layers (e.g., along the x-direction and arranged in the z-direction) of the semiconductor substrate 525 (e.g., not shown). The damage regions may correspond to contour lines (e.g., the second contour lines 250-b described with reference to FIG. 2B) extending along the y-direction and extending to a depth (e.g., in the z-direction) at least partially through the semiconductor substrate 525. The damage regions of the semiconductor substrate 525 may be associated with a relatively weak resistance to one or more forces (e.g., bending forces, tensile forces, shear forces) applied to the bonded wafer 515. For example, the damage regions may create a plane through the internal layers of the semiconductor substrate 525 which may be associated with an increased likelihood of fracture propagation through the semiconductor substrate 525 when applying one or more forces (e.g., bending forces, tensile forces, shear forces).

FIG. 5C illustrates a third processing step 500-c for applying one or more forces to the bonded wafer 515. The third processing step 500-c may include applying one or more mechanical forces to one or more of the substrates (e.g., the optically transmissive substrate 520, the semiconductor substrate 525) of the bonded wafer 515 to separate the bonded wafer 515 into respective dies. For example, as depicted in FIG. 5C, mechanical forces 560-b and 560-c may be applied to the optically transmissive substrate 520 (e.g., to surface 511), and a mechanical force 560-a may be applied to the semiconductor substrate 525 (e.g., to surface 516). In some aspects, the mechanical force 560-b and the mechanical force 560-c may be applied at a location adjacent to a contour line (e.g., a contour line corresponding to the damage regions and the damage tracks in the respective substrates). The respective locations of the mechanical force 560-b and the mechanical force 560-c may be some distance away from a contour line, where the distance is sufficient to bend and break both the optically transmissive substrate 520 and the semiconductor substrate 525 (e.g., to achieve a desired geometry corresponding to the contour line) with the application of the mechanical force 560-a, the mechanical force 560-b, and the mechanical force 560-c. Here, the distance of the mechanical force 560-b from the damage tracks and/or damage regions (e.g., d₀) and the distance of the mechanical force 560-c from the damage tracks and/or damage regions (e.g., d₁) may be about 10 μm, about 20 μm, about 25 μm, about 40 μm, about 45 μm, among other examples. The distance of the mechanical force 560-b and/or the mechanical force 560-c from the damage track and the damage regions may be based on one or more dimensions of the bonded wafer 515. A magnitude of each of the mechanical forces 560-a, 560-b, and 560-c may be configured to exceed the respective break resistance of the optically transmissive substrate 520 and the semiconductor substrate 525 (e.g., along a contour line). In some aspects, each of the mechanical forces 560-a, 560-b, and 560-c may be equal, or the mechanical forces 560-a, 560-b, and 560-c may be different.

In other examples, the bonded wafer 515 may be secured to a bending component, which may apply a mechanical force along one of the substrates of the bonded wafer 515. The one or more forces may be examples of tensile forces, bending forces, shear forces, compression forces, or a combination thereof, among other examples. Applying the mechanical forces may produce a bending stress within the bonded wafer 515 such that the damage tracks of the optically transmissive substrate 520 and the damage regions of the semiconductor substrate 525 may experience rapid crack propagation (e.g., fracture), thereby separating the bonded wafer 515. Due to the alignment of the damage tracks of the optically transmissive substrate 520 and the damage regions of the semiconductor substrate 525, the bonded wafer 515 may be accurately separated along a yz-plane.

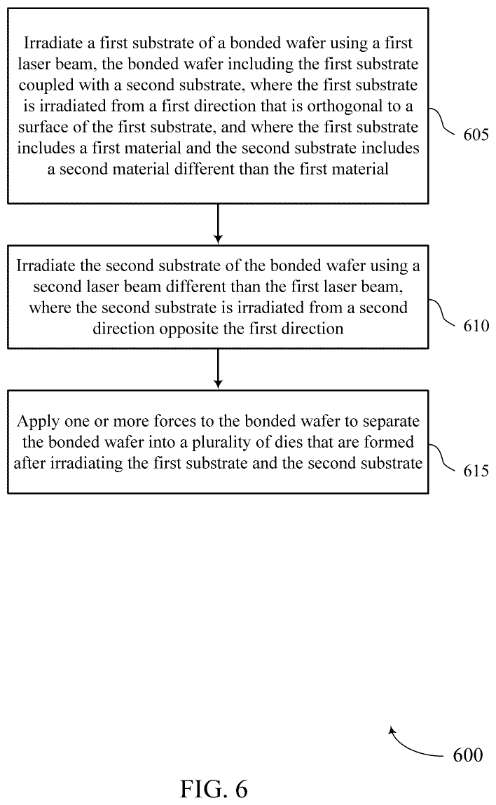

FIG. 6 shows a flowchart illustrating a method 600 that supports techniques for dicing bonded wafers using laser technologies in accordance with examples as disclosed herein. The operations of the method 600 may be implemented by a manufacturing system or one or more controllers associated with a manufacturing system. For example, the operations of the method 600 may be performed by one or more lasers on a bonded wafer including different materials, such as described with reference to FIGS. 1 through 5C. In some examples, one or more controllers may execute a set of instructions to control one or more functional elements of a manufacturing system to perform the described functions. Additionally, or alternatively, one or more controllers may perform aspects of the described functions using special-purpose hardware.

At 605, the method may include irradiating a first substrate of a bonded wafer using a first laser beam, the bonded wafer including the first substrate coupled with a second substrate, where the first substrate is irradiated from a first direction that is orthogonal to a surface of the first substrate, and where the first substrate includes a first material and the second substrate includes a second material different than the first material. The operations of 605 may be performed in accordance with examples as disclosed herein. In some examples, aspects of the operations of 605 may be performed by a first laser 105-a as described with reference to FIG. 1.

At 610, the method may include irradiating the second substrate of the bonded wafer using a second laser beam different than the first laser beam, where the second substrate is irradiated from a second direction opposite the first direction. The operations of 610 may be performed in accordance with examples as disclosed herein. In some examples, aspects of the operations of 610 may be performed by a second laser 105-b as described with reference to FIG. 1.

At 615, the method may include applying one or more forces to the bonded wafer to separate the bonded wafer into a plurality of dies that are formed after irradiating the first substrate and the second substrate. The operations of 615 may be performed in accordance with examples as disclosed herein. In some examples, aspects of the operations of 615 may be performed by mechanical forces as described with reference to FIG. 3C.

In some examples, an apparatus (e.g., a manufacturing system) as described herein may perform a method or methods, such as the method 600. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure: irradiating a first substrate of a bonded wafer using a first laser beam, the bonded wafer including the first substrate coupled with a second substrate, where the first substrate is irradiated from a first direction that is orthogonal to a surface of the first substrate, and where the first substrate includes a first material and the second substrate includes a second material different than the first material, irradiating the second substrate of the bonded wafer using a second laser beam different than the first laser beam, where the second substrate is irradiated from a second direction opposite the first direction, and applying one or more forces to the bonded wafer to separate the bonded wafer into a plurality of dies that are formed after irradiating the first substrate and the second substrate.

In some examples of the method 600 and the apparatus described herein, the first material includes a glass material and the second material includes a semiconductor material. In some examples of the method 600 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in the first direction. In some examples of the method 600 and the apparatus described herein, irradiating the first substrate may include operations, features, circuitry, logic, means, or instructions for forming a plurality of damage regions within a volume of the semiconductor material by focusing the second laser beam at a plurality of regions within the volume, the plurality of regions corresponding to one or more layers of irradiated semiconductor material, where the plurality of damage regions extend in the first direction or the second direction, or both, from each region of the plurality of regions.

In some examples, of the method 600 and the apparatus described herein, the first material includes a semiconductor material and the second material includes a glass material. In some examples of the method 600 and the apparatus described herein, irradiating the first substrate may include operations, features, circuitry, logic, means, or instructions for forming a plurality of damage regions within a volume of the semiconductor material by focusing the second laser beam at a plurality of regions within the volume, the plurality of regions corresponding to one or more layers of irradiated semiconductor material, where the plurality of damage regions extend in the first direction or the second direction, or both, from each region of the plurality of regions. In some examples of the method 600 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in the first direction.

In some examples of the method 600 and the apparatus described herein, the first substrate may be irradiated to form a plurality of contour lines in the bonded wafer and the method, apparatuses, and non-transitory computer-readable medium may include further operations, features, circuitry, logic, means, or instructions for aligning the second laser beam with the plurality of contour lines, where the second substrate may be irradiated based on aligning the second laser beam.

In some examples of the method 600 and the apparatus described herein, the second laser beam may be aligned based on a visual alignment with two or more fiducials, a visual alignment with a plurality of damage tracks or damage regions in the first substrate caused by the first laser beam, or both.

Some examples of the method 600 and the apparatus described herein may further include operations, features, means, or instructions for applying a tensile force or a bending force, or both, to the first substrate or to the second substrate when the one or more forces may be applied to the bonded wafer, where the bonded wafer may be separated into the plurality of dies based on the tensile force or the bending force, or both, and the one or more forces, the one or more forces being in the first direction or the second direction.

Some examples of the method 600 and the apparatus described herein may further include operations, features, means, or instructions for removing a portion of the first material, a portion of the second material, or both, to decrease a total thickness of the bonded wafer, where the portion of the first material or the portion of the second material, or both, may be removed prior to irradiating the first substrate and irradiating the second substrate, after irradiating the first substrate and prior to irradiating the second substrate, or after irradiating the first substrate and irradiating the second substrate.

In some examples of the method 600 and the apparatus described herein, the first substrate may be coupled with the second substrate prior to irradiating the first substrate and irradiating the second substrate, the first substrate and the second substrate being coupled via anodic bonding, adhesive bonding, fusion bonding, pressure bonding, chemical bonding, or any combination thereof.

In some examples of the method 600 and the apparatus described herein, the first laser beam includes a first pulsed laser beam having a first wavelength between about 500 nm and about 1100 nm and having a first pulse width between 10 femtoseconds and about 100 picoseconds and the second laser beam includes a second pulsed laser beam having a second wavelength between about 1000 nm and about 3000 nm and having a second pulse width between 10 femtoseconds and about 100 picoseconds.

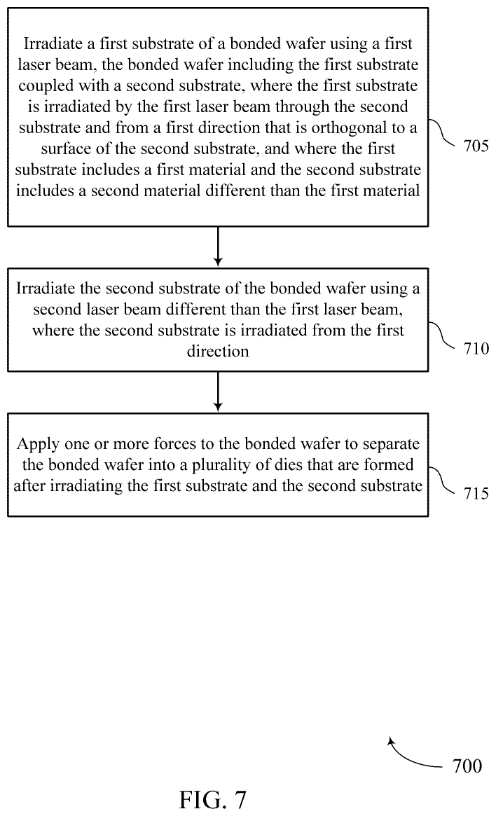

FIG. 7 shows a flowchart illustrating a method 700 that supports techniques for dicing bonded wafers using laser technologies in accordance with examples as disclosed herein. The operations of the method 700 may be implemented by a manufacturing system or one or more controllers associated with a manufacturing system. For example, the operations of the method 700 may be performed by one or more laser sources on a bonded wafer including different materials, such as described with reference to FIGS. 1 through 5C. In some examples, one or more controllers may execute a set of instructions to control one or more functional elements of a manufacturing system to perform the described functions. Additionally, or alternatively, one or more controllers may perform aspects of the described functions using special-purpose hardware.

At 705, the method may include irradiating a first substrate of a bonded wafer using a first laser beam, the bonded wafer including the first substrate coupled with a second substrate, where the first substrate is irradiated by the first laser beam through the second substrate and from a first direction that is orthogonal to a surface of the second substrate, and where the first substrate includes a first material and the second substrate includes a second material different than the first material. The operations of 705 may be performed in accordance with examples as disclosed herein. In some examples, aspects of the operations of 705 may be performed by a first laser 105-a or a second laser 105-b as described with reference to FIG. 1.

At 710, the method may include irradiating the second substrate of the bonded wafer using a second laser beam different than the first laser beam, where the second substrate is irradiated from the first direction. The operations of 710 may be performed in accordance with examples as disclosed herein. In some examples, aspects of the operations of 710 may be performed by a first laser 105-a or a second laser 105-b as described with reference to FIG. 1.

At 715, the method may include applying one or more forces to the bonded wafer to separate the bonded wafer into a plurality of dies that are formed after irradiating the first substrate and the second substrate. The operations of 715 may be performed in accordance with examples as disclosed herein. In some examples, aspects of the operations of 715 may be performed by the mechanical forces as described with reference to FIGS. 4C and 5C, respectively.

In some examples, an apparatus as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system) for irradiating a first substrate of a bonded wafer using a first laser beam, the bonded wafer including the first substrate coupled with a second substrate, where the first substrate is irradiated by the first laser beam through the second substrate and from a first direction that is orthogonal to a surface of the second substrate, and where the first substrate includes a first material and the second substrate includes a second material different than the first material, irradiating the second substrate of the bonded wafer using a second laser beam different than the first laser beam, where the second substrate is irradiated from the first direction, and applying one or more forces to the bonded wafer to separate the bonded wafer into a plurality of dies that are formed after irradiating the first substrate and the second substrate.

In some examples of the method 700 and the apparatus described herein, the first material includes a glass material and the second material includes a semiconductor material. In some examples of the method 700 and the apparatus described herein, irradiating the first substrate may include operations, features, circuitry, logic, means, or instructions for forming a plurality of damage regions within a volume of the semiconductor material by focusing the second laser beam through the glass material and at a plurality of regions within the volume, the plurality of regions corresponding to one or more layers of irradiated semiconductor material, where the plurality of damage regions extend in the first direction or a second direction opposite the first direction, or both, from each region of the plurality of regions. In some examples of the method 700 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending from a surface of the glass material to at least a depth of the glass material.

In some examples of the method 700 and the apparatus described herein, the glass material may be optically transmissive for a wavelength of the first laser beam.

In some examples of the method 700 and the apparatus described herein, the first material includes a semiconductor material and the second material includes a glass material. In some examples of the method 700 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending from a surface of the glass material to at least a depth of the glass material, where the surface of the glass material faces a surface of the semiconductor material. In some examples of the method 700 and the apparatus described herein, irradiating the first substrate may include operations, features, circuitry, logic, means, or instructions for forming a plurality of damage regions within a volume of the semiconductor material by focusing the second laser beam at a plurality of regions within the volume, the plurality of regions corresponding to one or more layers of irradiated semiconductor material, where the plurality of damage regions extend in the first direction or a second direction opposite the first direction, or both, from each region of the plurality of regions.

In some examples of the method 700 and the apparatus described herein, the semiconductor material may include a silicon-based material (e.g., a monocrystalline silicon) that is optically transmissive for a wavelength of the first laser beam.

In some examples of the method 700 and the apparatus described herein, the first substrate may be irradiated to form a plurality of contour lines in the bonded wafer and the method, apparatuses, and non-transitory computer-readable medium may include further operations, features, circuitry, logic, means, or instructions for aligning the second laser beam with the plurality of contour lines, where the second substrate may be irradiated based on aligning the second laser beam.

In some examples of the method 700 and the apparatus described herein, the second laser beam may be aligned based on a visual alignment with two or more fiducials, a visual alignment with a plurality of damage tracks or damage regions in the first substrate caused by the first laser beam, or both.

Some examples of the method 700 and the apparatus described herein may further include operations, features, means, or instructions for applying a tensile force or a bending force, or both, to the first substrate or to the second substrate, where the bonded wafer may be separated into the plurality of dies based on the tensile force or the bending force, or both.

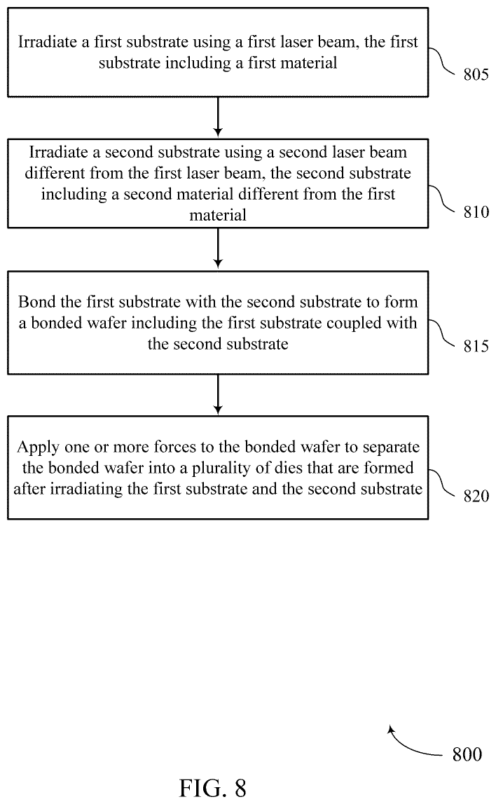

FIG. 8 shows a flowchart illustrating a method 800 that supports techniques for dicing bonded wafers using laser technologies in accordance with examples as disclosed herein. The operations of the method 800 may be implemented by a manufacturing system or one or more controllers associated with a manufacturing system. For example, the operations of the method 800 may be performed by one or more lasers on a bonded wafer including different materials, such as described with reference to FIGS. 1 through 5C. In some examples, one or more controllers may execute a set of instructions to control one or more functional elements of a manufacturing system to perform the described functions. Additionally, or alternatively, one or more controllers may perform aspects of the described functions using special-purpose hardware.

At 805, the method may include irradiating a first substrate using a first laser beam, the first substrate including a first material. The operations of 805 may be performed in accordance with examples as disclosed herein. In some examples, aspects of the operations of 805 may be performed by a first laser 105-a as described with reference to FIG. 1.

At 810, the method may include irradiating a second substrate using a second laser beam different from the first laser beam, the second substrate including a second material different from the first material. The operations of 810 may be performed in accordance with examples as disclosed herein. In some examples, aspects of the operations of 810 may be performed by a second laser 105-b as described with reference to FIG. 1.

At 815, the method may include bonding the first substrate with the second substrate to form a bonded wafer including the first substrate coupled with the second substrate. The operations of 820 may be performed in accordance with examples as disclosed herein.

At 820, the method may include applying one or more forces to the bonded wafer to separate the bonded wafer into a plurality of dies that are formed after irradiating the first substrate and the second substrate. The operations of 820 may be performed in accordance with examples as disclosed herein. In some examples, aspects of the operations of 820 may be performed by mechanical forces as described with reference to FIG. 3C.

In some examples, an apparatus (e.g., a manufacturing system) as described herein may perform a method or methods, such as the method 800. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure: irradiating a first substrate using a first laser beam, the first substrate including a first material, irradiating a second substrate using a second laser beam different from the first laser beam, the second substrate including a second material different from the first material, bonding the first substrate with the second substrate to form a bonded wafer including the first substrate coupled with the second substrate, and applying one or more forces to the bonded wafer to separate the bonded wafer into a plurality of dies that are formed after irradiating the first substrate and the second substrate.

In some examples of the method 800 and the apparatus described herein, the first material includes a glass material and the second material includes a semiconductor material. In some examples of the method 800 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in a first direction that is orthogonal to a surface of the first substrate. In some examples of the method 800 and the apparatus described herein, irradiating the first substrate may include operations, features, circuitry, logic, means, or instructions for forming a plurality of damage regions within a volume of the semiconductor material by focusing the second laser beam at a plurality of regions within the volume, the plurality of regions corresponding to one or more layers of irradiated semiconductor material, where the plurality of damage regions extend in the first direction or a second direction opposite the first direction, or both, from each region of the plurality of regions.

In some examples, of the method 800 and the apparatus described herein, the first material includes a semiconductor material and the second material includes a glass material. In some examples of the method 800 and the apparatus described herein, irradiating the first substrate may include operations, features, circuitry, logic, means, or instructions for forming a plurality of damage regions within a volume of the semiconductor material by focusing the second laser beam at a plurality of regions within the volume, the plurality of regions corresponding to one or more layers of irradiated semiconductor material, where the plurality of damage regions extend in a first direction or a second direction opposite the first direction, or both, from each region of the plurality of regions. In some examples of the method 800 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in the first direction that is orthogonal to a surface of the first substrate.

In some examples of the method 800 and the apparatus described herein, irradiating the first substrate may include operations, features, circuitry, logic, means, or instructions for bonding the first substrate with the second substrate via anodic bonding, adhesive bonding, fusion bonding, pressure bonding, chemical bonding, or any combination thereof.

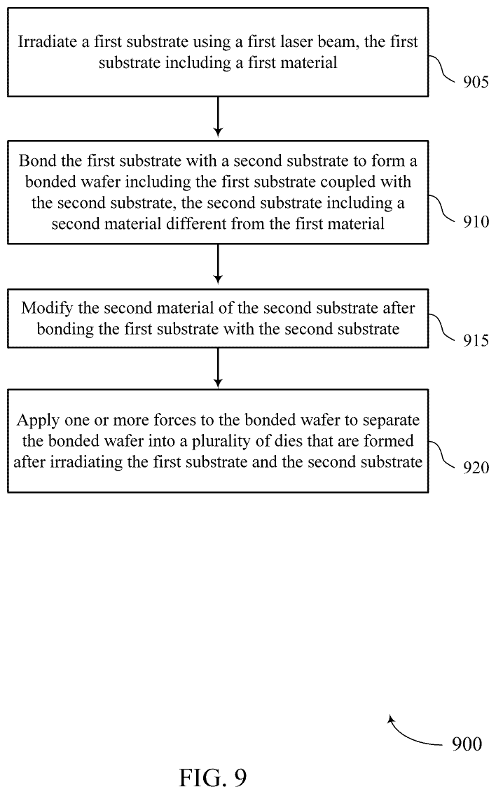

FIG. 9 shows a flowchart illustrating a method 900 that supports techniques for dicing bonded wafers using laser technologies in accordance with examples as disclosed herein. The operations of the method 900 may be implemented by a manufacturing system or one or more controllers associated with a manufacturing system. For example, the operations of the method 900 may be performed by one or more lasers on a bonded wafer including different materials, such as described with reference to FIGS. 1 through 5C. In some examples, one or more controllers may execute a set of instructions to control one or more functional elements of a manufacturing system to perform the described functions. Additionally, or alternatively, one or more controllers may perform aspects of the described functions using special-purpose hardware.

At 905, the method may include irradiating a first substrate using a first laser beam, the first substrate including a first material. The operations of 905 may be performed in accordance with examples as disclosed herein. In some examples, aspects of the operations of 905 may be performed by a first laser 105-a as described with reference to FIG. 1.

At 910, the method may include bonding the first substrate with a second substrate to form a bonded wafer including the first substrate coupled with the second substrate, the second substrate including a second material different from the first material. The operations of 910 may be performed in accordance with examples as disclosed herein.

At 915, the method may include modifying the second material of the second substrate after bonding the first substrate with the second substrate. The operations of 915 may be performed in accordance with examples as disclosed herein. In some examples, aspects of the operations of 915 may be performed by a second laser 105-b as described with reference to FIG. 1. In other examples, aspects of the operations of 915 may be performed using one or more mechanical tools, as described with reference to FIG. 1.

At 920, the method may include applying one or more forces to the bonded wafer to separate the bonded wafer into a plurality of dies that are formed after irradiating the first substrate and the second substrate. The operations of 920 may be performed in accordance with examples as disclosed herein. In some examples, aspects of the operations of 920 may be performed by mechanical forces as described with reference to FIG. 3C.

In some examples, an apparatus (e.g., a manufacturing system) as described herein may perform a method or methods, such as the method 900. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure: irradiating a first substrate using a first laser beam, the first substrate including a first material, bonding the first substrate with a second substrate to form a bonded wafer including the first substrate coupled with the second substrate, the second substrate including a second material different from the first material, modifying the second material of the second substrate after bonding the first substrate with the second substrate, and applying one or more forces to the bonded wafer to separate the bonded wafer into a plurality of dies that are formed after irradiating the first substrate and modifying the second substrate.

In some examples of the method 900 and the apparatus described herein, the first material includes a glass material and the second material includes a semiconductor material. In some examples of the method 900 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in a first direction that is orthogonal to a surface of the first substrate. In some examples of the method 900 and the apparatus described herein, irradiating the first substrate may include operations, features, circuitry, logic, means, or instructions for irradiating the second substrate using a second laser beam different from the first laser beam to form a plurality of damage regions within a volume of the semiconductor material by focusing a second laser beam at a plurality of regions within the volume, the plurality of regions corresponding to one or more layers of irradiated semiconductor material, where the plurality of damage regions extend in the first direction or a second direction opposite the first direction, or both, from each region of the plurality of regions.

In some examples of the method 900 and the apparatus described herein, the first material includes a semiconductor material and the second material includes a glass material. In some examples of the method 900 and the apparatus described herein, irradiating the first substrate may include operations, features, circuitry, logic, means, or instructions for irradiating the second substrate using a second laser beam different from the first laser beam to form a plurality of damage regions within a volume of the semiconductor material by focusing a second laser beam at a plurality of regions within the volume, the plurality of regions corresponding to one or more layers of irradiated semiconductor material, where the plurality of damage regions extend in a first direction or a second direction opposite the first direction, or both, from each region of the plurality of regions. In some examples of the method 900 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in the first direction that is orthogonal to a surface of the first substrate.

In some examples of the method 900 and the apparatus described herein, the first material includes a glass material and the second material includes a semiconductor material. In some examples of the method 900 and the apparatus described herein, irradiating the first substrate may include operations, features, circuitry, logic, means, or instructions for perforating the glass material using a plurality of pulses of the first laser beam to form a plurality of damage tracks, the plurality of damage tracks extending at least partially through the glass material in a first direction orthogonal to a surface of the first substrate. In some examples of the method 900 and the apparatus described herein, irradiating the first substrate may include operations, features, circuitry, logic, means, or instructions for removing a portion of the second material of the second substrate using one or more mechanical processes applied to a surface of the second substrate, where the one or more mechanical processes include sawing or blade scribing, or both.

In some examples of the method 900 and the apparatus described herein, the first material includes a semiconductor material and the second material includes a glass material. In some examples of the method 900 and the apparatus described herein, irradiating the first substrate may include operations, features, circuitry, logic, means, or instructions for irradiating the second substrate using a second laser beam different from the first laser beam to form a plurality of damage regions within a volume of the semiconductor material by focusing a second laser beam at a plurality of regions within the volume, the plurality of regions corresponding to one or more layers of irradiated semiconductor material, where the plurality of damage regions extend in a first direction or a second direction opposite the first direction, or both, from each region of the plurality of regions. In some examples of the method 900 and the apparatus described herein, irradiating the first substrate may include operations, features, circuitry, logic, means, or instructions for removing a portion of the second material of the second substrate using one or more mechanical processes applied to a surface of the second substrate, where the one or more mechanical processes include sawing or blade scribing, or both.

A bonded wafer is described. The bonded wafer may include an optically transmissive substrate layer coupled with a semiconductor substrate layer, where the optically transmissive substrate layer includes a plurality of damage tracks from a first laser source that extend at least partially from a surface of the optically transmissive substrate layer through a thickness of the optically transmissive substrate layer, and where the semiconductor substrate layer includes a plurality of regions that are damaged by a second laser source focused within a volume of the semiconductor substrate layer, where the plurality of damage tracks are aligned with the plurality of regions that are damaged and form one or more contour lines on the bonded wafer.

In some examples of the bonded wafer, the optically transmissive substrate layer includes a glass material having a thickness between about 100 μm and about 5 mm, and the semiconductor substrate layer includes a thickness between about 50 μm and about 1.5 mm.

In some examples of the bonded wafer, the plurality of damage tracks have a diameter of about 10 μm or less and the plurality of regions of the semiconductor substrate layer each include a respective damage region within the volume of the semiconductor substrate layer that originates in one or more directions from a portion of the semiconductor substrate layer modified by the second laser source.

It should be noted that these methods describe examples of implementations, and that the operations and the steps may be rearranged or otherwise modified such that other implementations are possible. In some examples, aspects from two or more of the methods may be combined. For example, aspects of each of the methods may include steps or aspects of the other methods, or other steps or techniques described herein. Thus, aspects of the disclosure may provide for consumer preference and maintenance interface.

The description set forth herein, in connection with the appended drawings, describes example configurations and does not represent all the examples that may be implemented or that are within the scope of the claims. The term “exemplary” used herein means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and devices are shown in block diagram form in order to avoid obscuring the concepts of the described examples.

The functions described herein may be implemented in hardware, software executed by a processor, firmware, or any combination thereof. If implemented in software executed by a processor, the functions may be stored on or transmitted over as one or more instructions or code on a computer-readable medium. Other examples and implementations are within the scope of the disclosure and appended claims. For example, due to the nature of software, functions described herein can be implemented using software executed by a processor, hardware, firmware, hardwiring, or combinations of any of these. Features implementing functions may also be physically located at various positions, including being distributed such that portions of functions are implemented at different physical locations.

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

In the appended figures, similar components or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

The description herein is provided to enable a person skilled in the art to make or use the disclosure. Various modifications to the disclosure will be readily apparent to those skilled in the art, and the generic principles defined herein may be applied to other variations without departing from the scope of the disclosure. Thus, the disclosure is not limited to the examples and designs described herein, but is to be accorded the broadest scope consistent with the principles and novel features disclosed herein.

What is claimed is:

1. A method, comprising:
irradiating a first substrate of a bonded wafer using a first laser beam, the bonded wafer comprising the first substrate coupled with a second substrate, wherein the first substrate is irradiated from a first direction that is orthogonal to a surface of the first substrate, and wherein the first substrate comprises a first material and the second substrate comprises a second material different than the first material;
irradiating the second substrate of the bonded wafer using a second laser beam different than the first laser beam, wherein the second substrate is irradiated from a second direction opposite the first direction; and
applying one or more forces to the bonded wafer to separate the bonded wafer into a plurality of dies that are formed after irradiating the first substrate and the second substrate.

2. The method of claim 1, wherein the first material comprises a glass material and the second material comprises a semiconductor material,
wherein irradiating the first substrate comprises:
perforating the glass material using a plurality of pulses of the first laser beam to form a plurality of damage tracks, the plurality of damage tracks extending at least partially through the glass material in the first direction, and
wherein irradiating the second substrate comprises:
forming a plurality of damage regions within a volume of the semiconductor material by focusing the second laser beam at a plurality of regions within the volume, the plurality of regions corresponding to one or more layers of irradiated semiconductor material, wherein the plurality of damage regions extend in the first direction or the second direction, or both, from each region of the plurality of regions.

3. The method of claim 1, wherein the first material comprises a semiconductor material and the second material comprises a glass material,
wherein irradiating the first substrate comprises:
forming a plurality of damage regions within a volume of the semiconductor material by focusing the second laser beam at a plurality of regions within the volume, the plurality of regions corresponding to one or more layers of irradiated semiconductor material, wherein the plurality of damage regions extend in the first direction or the second direction, or both, from each region of the plurality of regions, and
wherein irradiating the second substrate comprises:
perforating the glass material using a plurality of pulses of the first laser beam to form a plurality of damage tracks, the plurality of damage tracks extending at least partially through the glass material in the first direction.

4. The method of claim 1, wherein the first substrate is irradiated to form a plurality of contour lines in the bonded wafer, the method further comprising:
aligning the second laser beam with the plurality of contour lines, wherein the second substrate is irradiated based at least in part on aligning the second laser beam.

5. The method of claim 4, wherein the second laser beam is aligned based at least in part on a visual alignment with two or more fiducials, a visual alignment with a plurality of damage tracks or damage regions in the first substrate caused by the first laser beam, or both.

6. The method of claim 1, wherein applying the one or more forces to the bonded wafer comprises:
applying a tensile force or a bending force, or both, to the first substrate or to the second substrate, wherein the bonded wafer is separated into the plurality of dies based at least in part on the tensile force or the bending force, or both.

7. The method of claim 1, further comprising:
removing a portion of the first material, a portion of the second material, or both, to decrease a total thickness of the bonded wafer, wherein the portion of the first material or the portion of the second material, or both, are removed prior to irradiating the first substrate and irradiating the second substrate, after irradiating the first substrate and prior to irradiating the second substrate, or after irradiating the first substrate and irradiating the second substrate.

8. The method of claim 1, wherein the first substrate is coupled with the second substrate prior to irradiating the first substrate and irradiating the second substrate, the first substrate and the second substrate being coupled via anodic bonding, adhesive bonding, fusion bonding, pressure bonding, chemical bonding, or any combination thereof.

9. The method of claim 1, wherein:
the first laser beam comprises a first pulsed laser beam having a first wavelength between about 500 nanometers and about 1100 nanometers and having a first pulse width between 10 femtoseconds and about 100 picoseconds; and
the second laser beam comprises a second pulsed laser beam having a second wavelength between about 1000 nanometers and about 3000 nanometers and having a second pulse width between 10 femtoseconds and about 100 picoseconds.

10. A method, comprising:
irradiating a first substrate of a bonded wafer using a first laser beam, the bonded wafer comprising the first substrate coupled with a second substrate, wherein the first substrate is irradiated by the first laser beam through the second substrate and from a first direction that is orthogonal to a surface of the second substrate, and wherein the first substrate comprises a first material and the second substrate comprises a second material different than the first material;
irradiating the second substrate of the bonded wafer using a second laser beam different than the first laser beam, wherein the second substrate is irradiated from the first direction; and
applying one or more forces to the bonded wafer to separate the bonded wafer into a plurality of dies that are formed after irradiating the first substrate and the second substrate.

11. The method of claim 10, wherein the first material comprises a glass material and the second material comprises a semiconductor material,
wherein irradiating the first substrate comprises:
forming a plurality of damage regions within a volume of the semiconductor material by focusing the second laser beam through the glass material and at a plurality of regions within the volume, the plurality of regions corresponding to one or more layers of irradiated semiconductor material, wherein the plurality of damage regions extend in the first direction or a second direction opposite the first direction, or both, from each region of the plurality of regions, and
wherein irradiating the second substrate comprises:
perforating the glass material using a plurality of pulses of the first laser beam to form a plurality of damage tracks, the plurality of damage tracks extending from a surface of the glass material to at least a depth of the glass material.

12. The method of claim 11, wherein the glass material is optically transmissive for a wavelength of the first laser beam.

13. The method of claim 10, wherein the first material comprises a semiconductor material and the second material comprises a glass material,
wherein irradiating the first substrate comprises:
perforating the glass material using a plurality of pulses of the first laser beam to form a plurality of damage tracks, the plurality of damage tracks extending from a surface of the glass material to at least a depth of the glass material, wherein the surface of the glass material faces a surface of the semiconductor material, and
wherein irradiating the second substrate comprises:
forming a plurality of damage regions within a volume of the semiconductor material by focusing the second laser beam at a plurality of regions within the volume, the plurality of regions corresponding to one or more layers of irradiated semiconductor material, wherein the plurality of damage regions extend in the first direction or a second direction opposite the first direction, or both, from each region of the plurality of regions.

14. The method of claim 13, wherein the semiconductor material comprises a silicon-based material that is optically transmissive for a wavelength of the first laser beam.

15. The method of claim 10, wherein the first substrate is irradiated to form a plurality of contour lines in the bonded wafer, the method further comprising:
aligning the second laser beam with the plurality of contour lines, wherein the second substrate is irradiated based at least in part on aligning the second laser beam.

16. The method of claim 15, wherein the second laser beam is aligned based at least in part on a visual alignment with two or more fiducials, a visual alignment with a plurality of damage tracks or damage regions in the first substrate caused by the first laser beam, or both.

17. The method of claim 10, wherein applying the one or more forces to the bonded wafer comprises:
applying a tensile force or a bending force, or both, to the first substrate or to the second substrate, wherein the bonded wafer is separated into the plurality of dies based at least in part on the tensile force or the bending force, or both.

18. A method, comprising:
irradiating a first substrate using a first laser beam, the first substrate comprising a first material;
irradiating a second substrate using a second laser beam different from the first laser beam, the second substrate comprising a second material different from the first material;
bonding the first substrate with the second substrate to form a bonded wafer comprising the first substrate coupled with the second substrate; and
applying one or more forces to the bonded wafer to separate the bonded wafer into a plurality of dies that are formed after irradiating the first substrate and the second substrate.

19. The method of claim 18, wherein the first material comprises a glass material and the second material comprises a semiconductor material,
wherein irradiating the first substrate comprises:
perforating the glass material using a plurality of pulses of the first laser beam to form a plurality of damage tracks, the plurality of damage tracks extending at least partially through the glass material in a first direction that is orthogonal to a surface of the first substrate, and
wherein irradiating the second substrate comprises:
forming a plurality of damage regions within a volume of the semiconductor material by focusing the second laser beam at a plurality of regions within the volume, the plurality of regions corresponding to one or more layers of irradiated semiconductor material, wherein the plurality of damage regions extend in the first direction or a second direction opposite the first direction, or both, from each region of the plurality of regions.

20. The method of claim 18, wherein the first material comprises a semiconductor material and the second material comprises a glass material,
wherein irradiating the first substrate comprises:
forming a plurality of damage regions within a volume of the semiconductor material by focusing the second laser beam at a plurality of regions within the volume, the plurality of regions corresponding to one or more layers of irradiated semiconductor material, wherein the plurality of damage regions extend in a first direction or a second direction opposite the first direction, or both, from each region of the plurality of regions, and
wherein irradiating the second substrate comprises:
perforating the glass material using a plurality of pulses of the first laser beam to form a plurality of damage tracks, the plurality of damage tracks extending at least partially through the glass material in the first direction that is orthogonal to a surface of the first substrate.
